(19) United States
(12) Patent Application Publication
(10) Pub. No.: US 2023/0194973 A1
(43) Pub. Date: Jun. 22, 2023

(54) MASK BLANK, PHASE SHIFT MASK, METHOD OF MANUFACTURING PHASE SHIFT MASK, AND METHOD OF MANUFACTURING SEMICONDUCTOR DEVICE

(71) Applicant: HOYA CORPORATION, Tokyo (JP)

(72) Inventors: Osamu NOZAWA, Tokyo (JP); Keishi AKIYAMA, Tokyo (JP)

(73) Assignee: HOYA CORPORATION, Tokyo (JP)

(21) Appl. No.: 17/926,962

(22) PCT Filed: Jun. 15, 2021
(86) PCT No.: PCT/JP2021/022631

§ 371 Date: Nov. 21, 2022

(30) Foreign Application Priority Data
Jun. 30, 2020 (JP) 2020-112702

(51) Int. Cl. G03F 1/32

(52) U.S. Cl. CPC G03F 1/32

(57) ABSTRACT

Provided is a mask blank .

A transmittance adjusting film is provided on a phase shift film; the phase shift film generates a phase difference of 150 degrees or more and 210 degrees or less between an ArF excimer laser exposure light transmitted through the phase shift film and the exposure light transmitted through the air for a same distance as a thickness of the phase shift film; and a refractive index nu with respect to a wavelength of the exposure light, an extinction coefficient ku with respect to the wavelength of the exposure light, and a thickness du[nm] of the transmittance adjusting film satisfy both equations (1) and (2) given below.

$${\text{d}}_{\text{U}} \leq \text{-17} \text{.63} \times {\text{n}}_{\text{U}} {}^{\text{3}} \text{+142} \text{.0} \times {\text{n}}_{\text{U}} {}^{2} \text{-364} \text{.9} \times {\text{n}}_{\text{U}} \text{+315} \text{.8}$$

$${\text{d}}_{\text{U}} \geq \text{-2} \text{.805} \times {\text{k}}_{\text{U}} {}^{3} \text{+19} \text{.48} \times {\text{k}}_{\text{U}} {}^{\text{2}} \text{-43} \text{.58} \times {\text{k}}_{\text{U}} \text{+38} \text{.11}$$

### [CROSS-REFERENCE TO RELATED APPLICATIONS]

[0001a] This application is the National Stage of International Application No. PCT/JP2021/022631, filed Jun. 15, 2021, which claims priority to Japanese Patent Application No. 2020-112702, filed Jun. 30, 2020, and the contents of which is incorporated by reference.

### [TECHNICAL FIELD]

The present disclosure relates to a mask blank, a phase shift mask, a method of manufacturing a phase shift mask, and a method of manufacturing a semiconductor device.

### [BACKGROUND ART]

Generally, in the manufacturing process of a semiconductor device, the photolithography method is used to form a fine pattern. Multiple substrates called transfer masks are usually utilized in forming the fine pattern. In order to miniaturize the pattern of the semiconductor device, in addition to miniaturization of a mask pattern formed in a transfer mask, it is necessary to shorten the wavelength of an exposure light source used in photolithography. Recently, shortening of wavelength has been advancing from the use of a KrF excimer laser (wavelength 248 nm) to an ArF excimer laser (wavelength 193 nm) as an exposure light source in the manufacture of semiconductor devices.

As for the types of transfer masks, a half tone phase shift mask is known in addition to a conventional binary mask having a light-shielding pattern consisting of a chromium-based material on a transparent substrate. A molybdenum silicide (MoSi)-based material is widely used for a phase shift film of a half tone phase shift mask.

Patent Document 1 discloses a phase shift mask in which an etching stopper film 3 and a phase shift layer 4 forming a predetermined pattern are formed sequentially on a transparent substrate 2, in which a light shielding film pattern 5 consisting of chromium is formed on the phase shift layer 4 formed in region A, a semi-transparent film pattern 6 consisting of molybdenum silicide is formed on the phase shift layer 4 formed in region B, and a Levenson type phase shift mask and a half tone phase shift mask are formed on the same substrate.

Patent Document 2 discloses a phase shift mask including a half tone film 12 provided on a portion of a transparent substrate 11 where a light shielding pattern is formed and a portion of the same where a semi-light shielding pattern is formed, and a light shielding film 13 provided on the portion of the half tone film 12 where the light shielding pattern is formed in the half tone film 12. The semi-light shielding pattern includes a first semi-light shielding pattern consisting of the half tone film 12 and a second semi-light shielding pattern consisting of a half tone film having a dimension smaller than the first semi-light shielding pattern, and in a light transmitting path 32 of a region including the second semi-light shielding pattern, elements for adjusting light transmittance of the light transmitting path 32 are included.

### [PRIOR ART PUBLICATIONS]

### [Patent Documents]

### [Patent Document 1]

Japanese Patent Application Publication H06-123961

### [Patent Document 2]

Japanese Patent Application Publication 2007-279441

### [SUMMARY OF THE DISCLOSURE]

### [Problems to Be Solved by the Disclosure]

In recent years, types of required patterns have become more diverse and complex, and finer patterns and relatively sparse patterns may coexist in a transfer pattern to be formed in a half tone phase shift mask. The optimum transmittance to obtain a good phase shift effect may vary depending on the type of pattern. In other words, depending on the type, pitch, etc. of the pattern to be transferred, it may be preferable to increase or reduce the transmittance. Further, since how to set the regions with relatively high transmittance and regions with relatively low transmittance in a transfer region varies according to the semiconductor device as a transfer target, there is a need for mask blanks with a high degree of freedom in design which enable setting regions with desired transmittance in accordance with the types of patterns to be formed in the transfer target.

The phase shift mask of Patent Document 1 has a light shielding film pattern formed in region A and a semi-transparent film pattern formed in another region B, and this phase shift mask itself is useful. However, this phase shift mask has a Levenson type phase shift pattern provided in the region A and a half tone type phase shift pattern provided in the region B, which means patterns that generate different phase shift effects coexist in plan view. This phase shift mask did not meet the requirement of a half tone phase shift mask providing a half tone phase shift pattern with different transmittances.

Further, the phase shift mask of Patent Document 2 requires the process to implant Ga ions into a half tone mask blank to reduce light transmittance of the implanted region. Such a process is not performed in an ordinary mask making process, and since a mask manufacturing apparatus should be provided with an ion implantation mechanism, the mask manufacturing process will become more complicated. Further, since the ions implanted into the mask blank may diffuse out of the desired region, it was difficult to meet the requirements of fine pattern manufacture.

The present disclosure was made to solve the conventional problems, and an aspect of the present disclosure is to provide a mask blank including a phase shift film on a transparent substrate in which patterns with different transmittances can be formed with desired precision without causing complication in the process of manufacturing a phase shift mask from a mask blank (mask manufacturing process), and a desired phase shift function in each of the patterns can be obtained. A further aspect is to provide a phase shift mask manufactured using this mask blank and a method of manufacturing the phase shift mask. Yet another aspect of the present disclosure is to provide a method of manufacturing a semiconductor device using such a phase shift mask.

### [Means for Solving the Problems]

For solving the above problems, the present disclosure includes the following configurations.

### (Configuration 1)

A mask blank including:
a phase shift film on a transparent substrate; and
a transmittance adjusting film on the phase shift film,
in which the phase shift film generates a phase difference of 150 degrees or more and 210 degrees or less between an exposure light of an ArF excimer laser transmitted through the phase shift film and the exposure light transmitted through the air for a same distance as a thickness of the phase shift film, and
in which a refractive index nᵤ with respect to a wavelength of the exposure light, an extinction coefficient kᵤ with respect to the wavelength of the exposure light, and a thickness dᵤ[nm] of the transmittance adjusting film satisfy both relationships according to Equation (1) and Equation (2) given below.
$${\text{d}}_{\text{U}} \leq - 17.63 \times {\text{n}}_{\text{U}} {}^{3} + 142.0 \times {\text{n}}_{\text{U}} {}^{2} - 364.9 \times {\text{n}}_{\text{U}} + 315.8$$
$${\text{d}}_{\text{U}} \geq - 2.805 \times {\text{k}}_{\text{U}} {}^{3} + 19.48 \times {\text{k}}_{\text{U}} {}^{2} - 43.58 \times {\text{k}}_{\text{U}} + 38.11$$

### (Configuration 2)

The mask blank according to Configuration 1, in which the refractive index nᵤ of the transmittance adjusting film is 1.2 or more.

### (Configuration 3)

The mask blank according to Configuration 1 or 2, in which the extinction coefficient kᵤ of the transmittance adjusting film is 1.5 or more.

### (Configuration 4)

The mask blank according to any of Configurations 1 to 3, in which the phase shift film transmits the exposure light with a transmittance of 12% or more.

### (Configuration 5)

The mask blank according to any of Configurations 1 to 4, in which the extinction coefficient kᵤ and the thickness dᵤ[nm] of the transmittance adjusting film satisfy a relationship according to Equation (3) given below.

$${\text{d}}_{\text{U}} \leq 8.646 \times {\text{k}}_{\text{U}} {}^{2} - 38.42 \times {\text{k}}_{\text{U}} + 61.89$$

### (Configuration 6)

The mask blank according to any of Configurations 1 to 5, in which the transmittance adjusting film contains silicon and nitrogen.

### (Configuration 7)

The mask blank according to any of Configurations 1 to 6 including an intermediate film containing silicon and oxygen between the phase shift film and the transmittance adjusting film.

### (Configuration 8)

The mask blank according to any of Configurations 1 to 6, in which the phase shift film includes an uppermost layer containing silicon and oxygen on a surface that is opposite to the transparent substrate side.

### (Configuration 9)

The mask blank according to any of Configurations 1 to 8 including a light shielding film on the transmittance adjusting film.

### (Configuration 10)

A phase shift mask including:
a phase shift film having a first pattern on a transparent substrate; and
a transmittance adjusting film having a second pattern on the phase shift film,
in which the phase shift film generates a phase difference of 150 degrees or more and 210 degrees or less between an exposure light of an ArF excimer laser transmitted through the phase shift film and the exposure light transmitted through the air for a same distance as a thickness of the phase shift film, and
in which a refractive index nᵤ with respect to a wavelength of the exposure light, an extinction coefficient kᵤ with respect to the wavelength of the exposure light, and a thickness dᵤ[nm] of the transmittance adjusting film satisfy both relationships according to Equation (1) and Equation (2) given below.
$${\text{d}}_{\text{U}} \leq - 17.63 \times {\text{n}}_{\text{U}} {}^{3} + 142.0 \times {\text{n}}_{\text{U}} {}^{2} - 364.9 \times {\text{n}}_{\text{U}} + 315.8$$
$${\text{d}}_{\text{U}} \geq - 2.805 \times {\text{k}}_{\text{U}} {}^{3} + 19.48 \times {\text{k}}_{\text{U}} {}^{2} - 43.58 \times {\text{k}}_{\text{U}} + 38.11$$

### (Configuration 11)

The phase shift mask according to Configuration 10, in which the refractive index nᵤ of the transmittance adjusting film is 1.2 or more.

### (Configuration 12)

The phase shift mask according to Configuration 10 or 11, in which the extinction coefficient kᵤ of the transmittance adjusting film is 1.5 or more.

### (Configuration 13)

The phase shift mask according to any of Configurations 10 to 12, in which the phase shift film transmits the exposure light with a transmittance of 12% or more.

### (Configuration 14)

The phase shift mask according to any of Configurations 10 to 13, in which the extinction coefficient kᵤ and the thickness dᵤ[nm]of the transmittance adjusting film satisfy a relationship according to Equation (3) given below.

$${\text{d}}_{\text{U}} \leq 8.646 \times {\text{k}}_{\text{U}} {}^{2} - 38.42 \times {\text{k}}_{\text{U}} + 61.89$$

### (Configuration 15)

The phase shift mask according to any of Configurations 10 to 14, in which the transmittance adjusting film contains silicon and nitrogen.

### (Configuration 16)

The phase shift mask according to any of Configurations 10 to 15 including an intermediate film having the second pattern between the phase shift film and the transmittance adjusting film, in which the intermediate film contains silicon and oxygen.

### (Configuration 17)

The phase shift mask according to any of Configurations 10 to 15, in which the phase shift film includes an uppermost layer containing silicon and oxygen on a surface that is opposite to the transparent substrate side.

### (Configuration 18)

The phase shift mask according to any of Configurations 10 to 17 including a light shielding film having a third pattern on the transmittance adjusting film.

### (Configuration 19)

A method of manufacturing a phase shift mask using the mask blank according to Configuration 9, including the steps of:
forming a first pattern in the light shielding film by dry etching;
forming a first pattern in each of the transmittance adjusting film and the phase shift film by dry etching with a light shielding film having the first pattern as a mask;
forming a second pattern in the light shielding film by dry etching;
forming a second pattern in the transmittance adjusting film by dry etching with a light shielding film having the second pattern as a mask; and
forming a third pattern in the light shielding film by dry etching.

### (Configuration 20)

A method of manufacturing a semiconductor device including the step of transferring a transfer pattern to a resist film on a semiconductor substrate by exposure using the phase shift mask according to Configuration 18.

### [Effect of the Disclosure]

The present disclosure can provide a mask blank in which patterns with different transmittances can be formed in desired precision without causing complication in the mask manufacturing process, and a desired phase shift function in each of the patterns can be obtained.

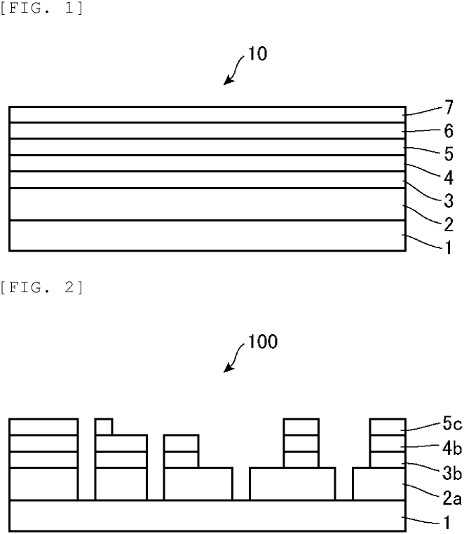

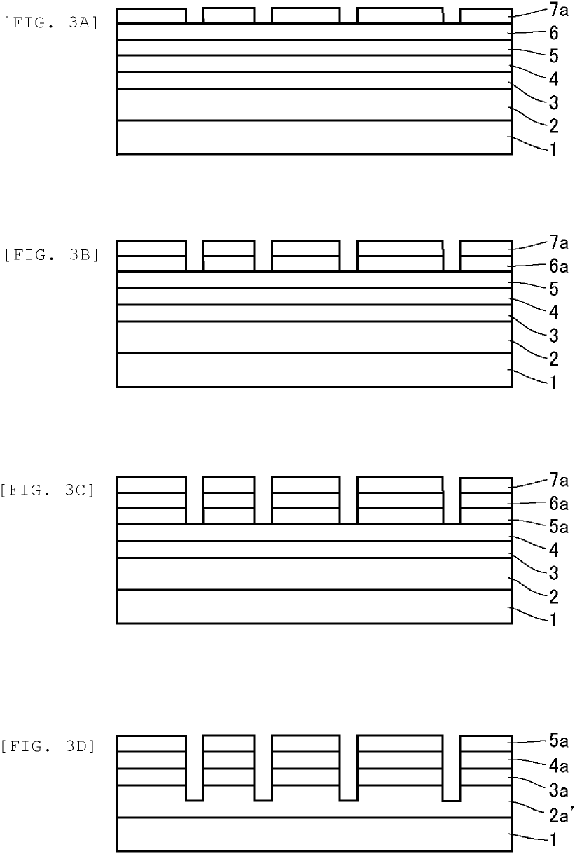

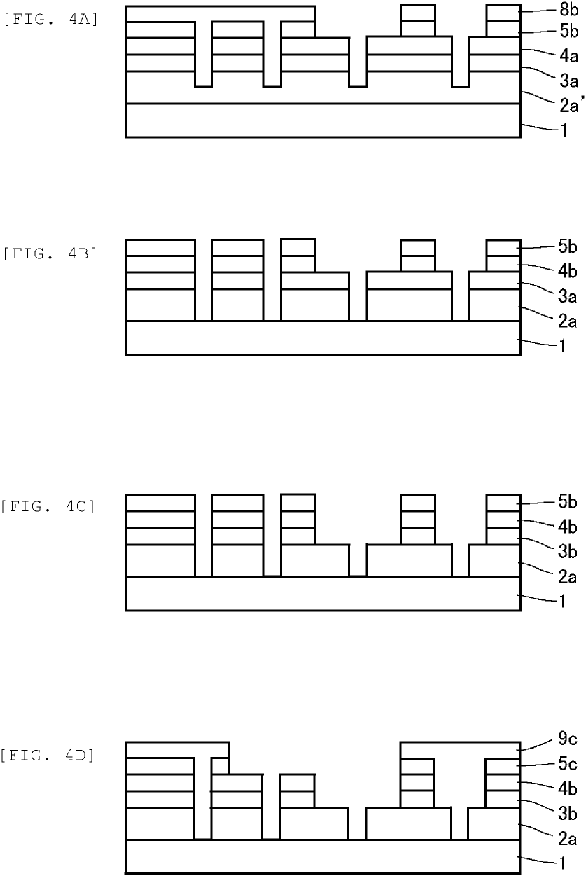

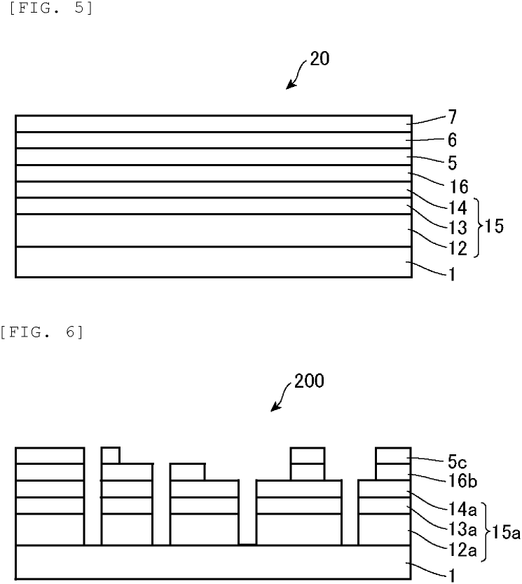

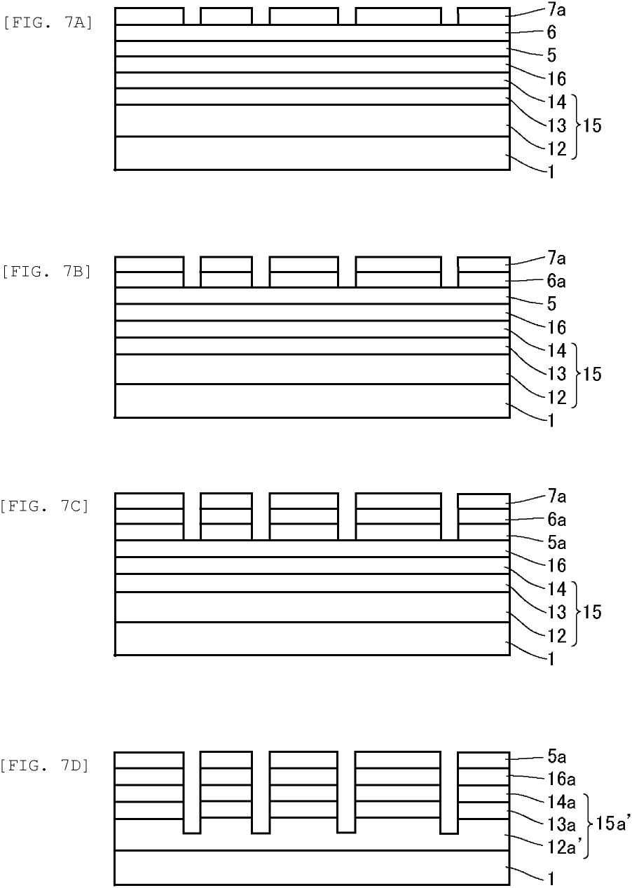

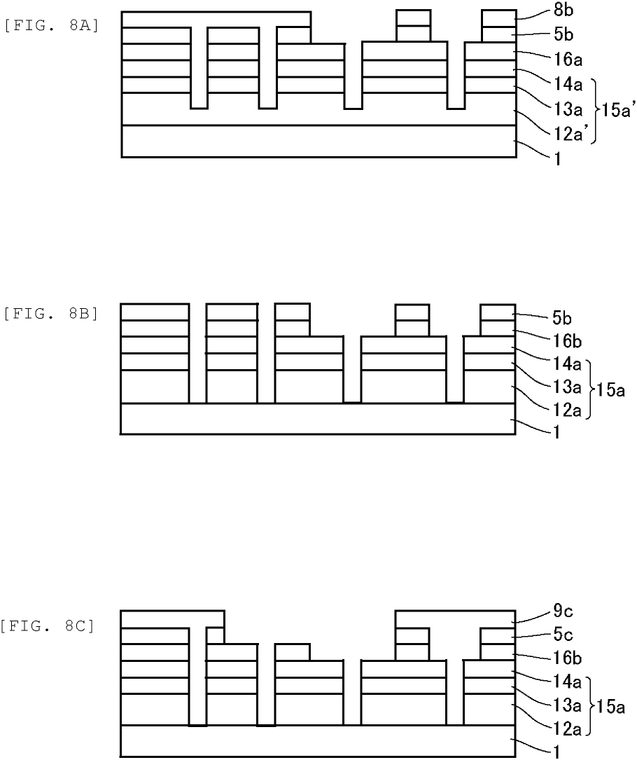

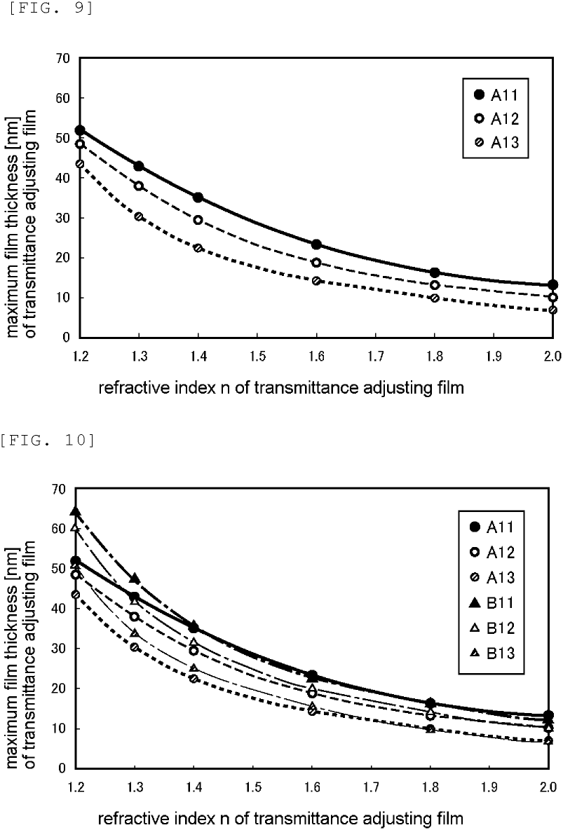

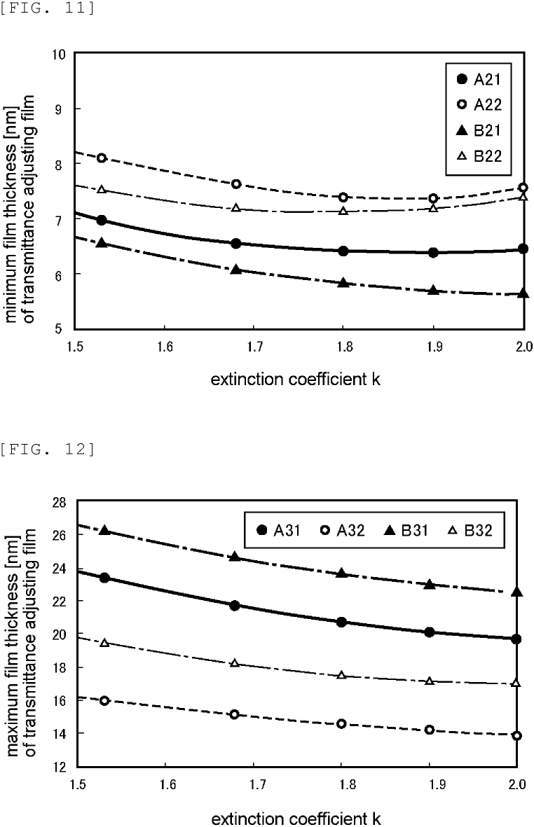

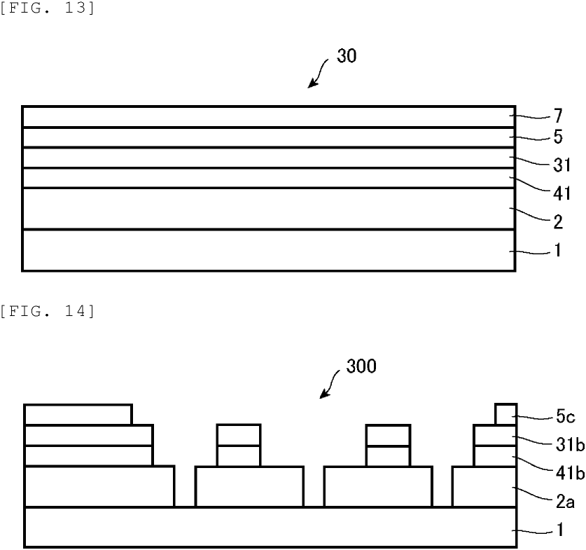

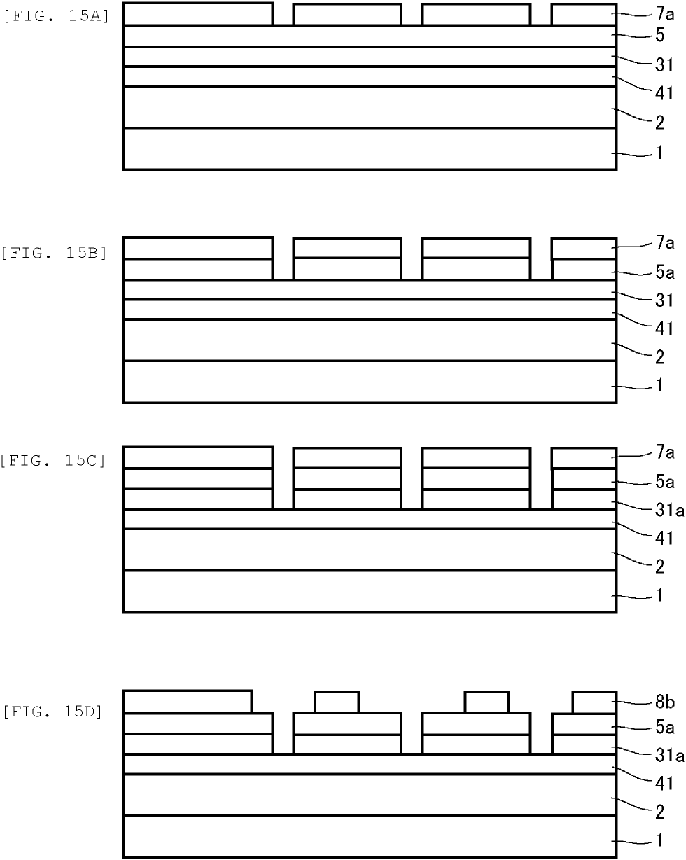

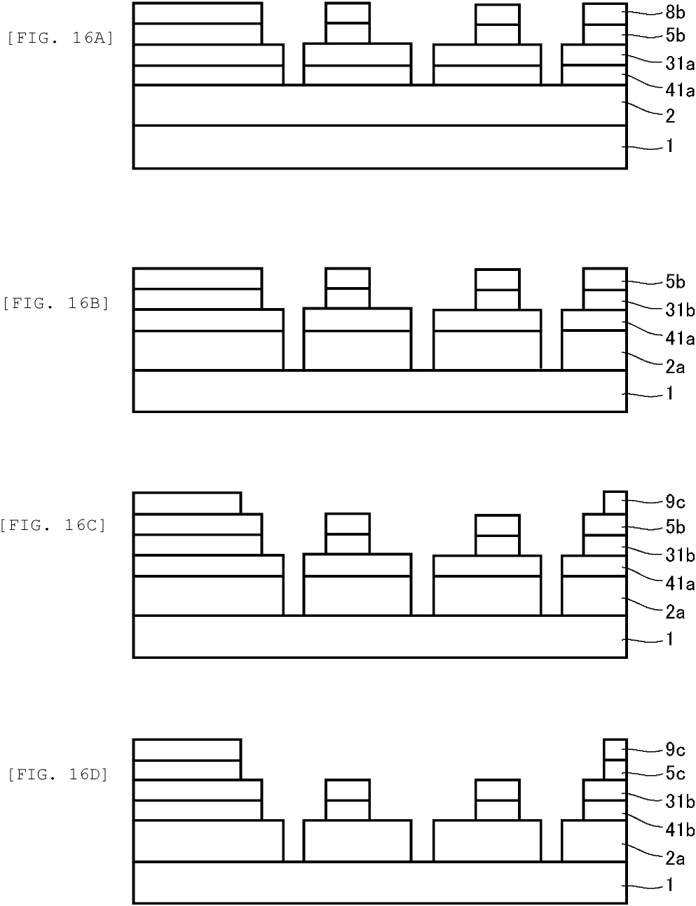

### [BRIEF DESCRIPTION OF THE DRAWINGS]

[FIG. 1] FIG. 1 is a cross-sectional view showing a configuration of the mask blank of the first embodiment of the present disclosure.

[FIG. 2] FIG. 2 is a cross-sectional view showing a configuration of the phase shift mask of the first embodiment of the present disclosure.

[FIGS. 3A-3D] FIGS. 3A-3D are schematic cross-sectional views showing a principal part of the manufacturing process of the phase shift mask of the first embodiment of the present disclosure.

[FIGS. 4A-4D] FIGS. 4A-4D are schematic cross-sectional views showing a principal part of the manufacturing process of the phase shift mask of the first embodiment of the present disclosure.

[FIG. 5] FIG. 5 is a cross-sectional view showing a configuration of the mask blank of the second embodiment of the present disclosure.

[FIG. 6] FIG. 6 is a cross-sectional view showing a configuration of the phase shift mask of the second embodiment of the present disclosure.

[FIGS. 7A-7D] FIGS. 7A-7D Re schematic cross-sectional views showing a principal part of the manufacturing process of the phase shift mask of the second embodiment of the present disclosure.

[FIGS. 8A-8C] FIGS. 8A-8C are schematic cross-sectional views showing a principal part of the manufacturing process of the phase shift mask of the second embodiment of the present disclosure.

[FIG. 9] FIG. 9 shows the relationship between the maximum film thickness and the refractive index n of the transmittance adjusting film to satisfy the condition that the increased amount in phase difference is in a predetermined value or less, as derived from the results of the optical simulation A1.

[FIG. 10] FIG. 10 shows the relationship between the maximum film thickness and the refractive index n of the transmittance adjusting film to satisfy the condition that the increased amount in phase difference is in a predetermined value or less, as derived from the results of the optical simulations A1 and B1.

[FIG. 11] FIG. 11 shows the relationship between the minimum film thickness and the extinction coefficient k of the transmittance adjusting film to satisfy the condition that the ratio of transmittance is in a predetermined value or less, as derived from the results of the optical simulations A2 and B2.

[FIG. 12] FIG. 12 shows the relationship between the maximum film thickness and the extinction coefficient k of the transmittance adjusting film to satisfy the condition that the transmittance of exposure light transmitted through the stacked structure of the phase shift film and the transmittance adjusting film is in a predetermined value or more, as derived from the results of the optical simulations A3 and B3.

[FIG. 13] FIG. 13 is a cross-sectional view showing a configuration of the mask blank of the third embodiment of the present disclosure.

[FIG. 14] FIG. 14 is a cross-sectional view showing a configuration of the phase shift mask of the third embodiment of the present disclosure.

[FIGS. 15A-15D] FIGS. 15A-15D are schematic cross-sectional views showing a principal part of the manufacturing process of the phase shift mask of the third embodiment of the present disclosure.

[FIGS. 16A-16D] FIGS. 16A-16D are schematic cross-sectional view showing a principal part of the manufacturing process of the phase shift mask of the third embodiment of the present disclosure.

### [EMBODIMENTS FOR CARRYING OUT THE DISCLOSURE]

The embodiments of the present disclosure are explained below. The inventors of the present disclosure studied diligently on means which enable to form patterns with different transmittances in a phase shift film with desired precision without causing complication in the mask manufacturing process, and which also enable to obtain a desired phase shift function in each of the patterns.

First, the inventors conceived a configuration in which a transmittance adjusting film is provided on a phase shift film in order to create patterns with different transmittances. The phase shift film that has been employed has a function to generate a phase difference of 150 degrees or more and 210 degrees or less between an exposure light of an ArF excimer laser transmitted through the phase shift film and the exposure light transmitted through the air for the same distance as the thickness of the phase shift film (hereinafter the function is referred to as “desired phase shift function” as necessary). Through the above configuration, the exposure light of the ArF excimer laser (hereafter referred to as “exposure light” as necessary) can be transmitted through the phase shift film in a predetermined transmittance in the portion, on the phase shift mask, where the transmittance adjusting film was removed, and the desired phase shift function described above can be obtained.

Moreover, the inventors further studied the configuration of a transmittance adjusting film which enables to obtain a desired phase shift function with respect to an exposure light transmitted through the phase shift film and the transmittance adjusting film as well, and which enables to obtain the transmittance that significantly differs from the transmittance of the exposure light transmitted through the phase shift film.

First, regarding the phase shift function, the inventors examined the conditions for satisfying that the increased amount in phase difference of the exposure light transmitted through the stacked structure of the phase shift film and the transmittance adjusting film with respect to the exposure light transmitted through the phase shift film is 20 degrees or less. In this study, the inventors focused on the relationship between the maximum film thickness and the refractive index n of the transmittance adjusting film, and conducted an optical simulation A1 for the phase shift film and the transmittance adjusting film. In the optical simulation A1, the maximum film thickness of the transmittance adjusting film was calculated to satisfy the condition that the increased amount in phase difference is 20 degrees or less while changing the film thickness of the transmittance adjusting film within the refractive index n ranging between 1.2 and 2.0. The phase shift film herein had the film thickness of 60.4 nm, the refractive index n of 2.61, and the extinction coefficient k of 0.36. The above refractive index n and extinction coefficient k are values with respect to the wavelength of the ArF excimer laser light (wavelength: 193 nm), and the same applies hereafter unless otherwise mentioned.

In the optical simulation A1, an intermediate film was set between the phase shift film and the transmittance adjusting film. This intermediate film was provided assuming that etching was controlled not to be conducted up to the phase shift film when the transmittance adjusting film is patterned by dry etching. The intermediate film had the film thickness of 3 nm, the refractive index n of 1.56, and the extinction coefficient k of 0.00. Due to such optical characteristics of the intermediate film, its effect on the results of the optical simulation A1 is negligible.

Based on the results of the optical simulation A1, the relationship between the refractive index n and the maximum film thickness of the transmittance adjusting film was identified. FIG. 9 shows the relationship between the maximum film thickness and the refractive index n of the transmittance adjusting film to satisfy the condition that the increased amount in phase difference of the exposure light transmitted through the stacked structure of the phase shift film and the transmittance adjusting film with respect to the exposure light transmitted through the phase shift film is 20 degrees or less, as derived from the results of the optical simulation A1. The curves A11, A12, and A13 in FIG. 9 show the maximum film thickness of the transmittance adjusting film to satisfy the conditions that the increased amount in phase difference is 20 degrees or less, 15 degrees or less, and 10 degrees or less, respectively.

The relational equation (equation of the curve A11) of the maximum film thickness of the transmittance adjusting film to satisfy the condition that the increased amount in phase difference is 20 degrees or less shown in FIG. 9 is as follows.

$${\text{d}}_{\text{Umax}} = - 17.63 \times {\text{n}}_{\text{U}} {}^{3} + 142.0 \times {\text{n}}_{\text{U}} {}^{2} - 364.9 \times {\text{n}}_{\text{U}} + 315.8$$

As shown in FIG. 9, the curves A12 and A13 are located below the curve A11, the curves A12 and A13 satisfying the condition that the increased amount in phase difference is 15 degrees or less and 10 degrees or less. The relational equation (equation of the curve A12) of the maximum film thickness of the transmittance adjusting film to satisfy the condition that the increased amount in phase difference is 15 degrees or less is as follows.

$${\text{d}}_{\text{Umax}} = - 70.62 \times {\text{n}}_{\text{U}} {}^{3} + 406.5 \times {\text{n}}_{\text{U}} {}^{2} - 795.7 \times {\text{n}}_{\text{U}} + 540.1$$

Furthermore, the relational equation (equation of the curve A13) of the maximum film thickness of the transmittance adjusting film to satisfy the condition that the increased amount in phase difference is 10 degrees or less is as follows.

$${\text{d}}_{\text{Umax}} = 201.1 \times {\text{n}}_{\text{U}} {}^{4} - 1407 \times {\text{n}}_{\text{U}} {}^{3} + 3700 \times {\text{n}}_{\text{U}} {}^{2} - 4356 \times {\text{n}}_{\text{U}} + 1956$$

From these results, the inventors found that when the film thickness dᵤ[nm]and the refractive index nᵤ of the transmittance adjusting film satisfy

$${\text{d}}_{\text{U}} \leq - 17.63 \times {\text{n}}_{\text{U}} {}^{3} + 142.0 \times {\text{n}}_{\text{U}} {}^{2} - 364.9 \times {\text{n}}_{\text{U}} + 315.8 ,$$

the increased amount in phase difference of the exposure light transmitted through the stacked structure of the phase shift film and the transmittance adjusting film with respect to the exposure light transmitted through the phase shift film becomes 20 degrees or less.

In addition, the inventors found that when the film thickness dᵤ[nm]and the refractive index n_{U} of the transmittance adjusting film satisfy

$${\text{d}}_{\text{U}} \leq - 70.62 \times {\text{n}}_{\text{U}} {}^{3} + 406.5 \times {\text{n}}_{\text{U}} {}^{2} - 795.7 \times {\text{n}}_{\text{U}} + 540.1 ,$$

the increased amount in phase difference of the exposure light transmitted through the stacked structure of the phase shift film and the transmittance adjusting film with respect to the exposure light transmitted through the phase shift film becomes 15 degrees or less.

Furthermore, the inventors found that when the film thickness dᵤ[nm]and the refractive index nᵤ of the transmittance adjusting film satisfy

$${\text{d}}_{\text{U}} \leq 201.1 \times {\text{n}}_{\text{U}} {}^{4} - 1407 \times {\text{n}}_{\text{U}} {}^{3} + 3700 \times {\text{n}}_{\text{U}} {}^{2} - 4356 \times {\text{n}}_{\text{U}} + 1956 ,$$

the increased amount in phase difference of the exposure light transmitted through the stacked structure of the phase shift film and the transmittance adjusting film with respect to the exposure light transmitted through the phase shift film becomes 10 degrees or less.

Furthermore, the inventors conducted the same optical simulation B1 with different conditions of the phase shift film. The phase shift film was made to have a structure where a first layer, a second layer, and a third layer are stacked from the transparent substrate side. The first layer had the film thickness of 41 nm, the refractive index n of 2.61, and the extinction coefficient k of 0.36. The second layer had the film thickness of 24 nm, the refractive index n of 2.18, and the extinction coefficient k of 0.12. The third layer had the film thickness of 4 nm, the refractive index n of 1.56, and the extinction coefficient k of 0.00. In the optical simulation B, the phase shift film was configured without an intermediate film between the phase shift film and the transmittance adjusting film, since the third layer can also function as the intermediate film described above. Based on the results of the optical simulation B1, the relationship between the refractive index n and the maximum film thickness of the transmittance adjusting film was organized.

FIG. 10 shows a comparison between the results of the optical simulation A1 and the optical simulation B1 regarding the relationship between the maximum film thickness and the refractive index n of the transmittance adjusting film. The curves A11, A12, and A13 shown in FIG. 10 are the result of the optical simulation A1 and are the same as those illustrated in FIG. 9. The curves B11, B12, and B13 shown in FIG. 10 respectively show the result of the optical simulation B1, showing the maximum film thickness of the transmittance adjusting film to satisfy the conditions that the increased amount in phase difference is 14 degrees or less, 11 degrees or less, and 6 degrees or less, respectively.

In FIG. 10, the curve All is below the curve B11 (curve of threshold in which the increased amount in phase difference is 14 degrees). This indicates that the transmittance adjusting film that satisfies the relationship of the equation (1) derived based on the curve A11 has the increased amount in phase difference of 14 degrees or less even when the transmittance adjusting film is provided on the phase shift film used in the optical simulation B1. Similarly, the curve A12 is below the curve B12. This indicates that the transmittance adjusting film that satisfies the relationship of the equation (1-A12) derived based on the curve A12 has the increased amount in phase difference of 11 degrees or less even when the transmittance adjusting film is provided on the phase shift film used in the optical simulation B1. Similarly, the curve A13 is below the curve B13. This indicates that the transmittance adjusting film that satisfies the relationship of the equation (1-A13) derived based on the curve A13 have the increased amount in phase difference of 6 degrees or less even when the transmittance adjusting film is provided on the phase shift film used in the optical simulation B1. These results indicate that the transmittance adjusting film that satisfies the relationship of the equation (1) has the above-mentioned increased amount in phase difference of 20 degrees or less, regardless of the optical characteristics of the phase shift film provided thereunder.

On the other hand, the inventors studied the condition that the ratio of the transmittance Ts of the exposure light transmitted through the stacked structure of the phase shift film and the transmittance adjusting film with respect to the transmittance Tp of the exposure light transmitted through the phase shift film (i.e., Ts/Tp; hereafter may be simply referred to as transmittance ratio) is 0.5 or less, as a condition to obtain the transmittance that significantly differs from the transmittance of the exposure light transmitted through the phase shift film. In this study, the inventors focused on the relationship between the minimum film thickness and the extinction coefficient k of the transmittance adjusting film, and conducted optical simulations A2 and B2 for the phase shift film and the transmittance adjusting film, respectively. In the optical simulations A2 and B2, the minimum film thickness of the transmittance adjusting film was calculated to satisfy the condition that the transmittance ratio is 0.5 or less while changing the film thickness of the transmittance adjusting film within the extinction coefficient k ranging between 1.5 and 2.0. As for the phase shift film, the same film as in the optical simulation A1 was used in the optical simulation A2, and the same film as in the optical simulation B1 was used in the optical simulation B2.

Thereafter, based on each result of the optical simulations A2 and B2, the relationship between the extinction coefficient k and the minimum film thickness of the transmittance adjusting film was organized. FIG. 11 shows the comparison between the results of the optical simulation A2 and the optical simulation B2 regarding the relationship between the minimum film thickness and the extinction coefficient k of the transmittance adjusting film. The curves A21 and A22 in FIG. 11 show the results of the optical simulation A2, each showing the minimum film thickness of the transmittance adjusting film to satisfy the conditions that the transmittance ratio is 0.50 or less, and 0.45 or less, respectively. The curves B21 and B22 show the results of the optical simulation B2, showing the minimum film thickness of the transmittance adjusting film to satisfy the condition that the transmittance ratio is 0.50 or less, and 0.43 or less, respectively.

The relational equation (equation of the curve A21) of the minimum film thickness of the transmittance adjusting film to satisfy the condition that the transmittance ratio is 0.5 or less shown in FIG. 11 is as follows.

$${\text{d}}_{\text{Umin}} = - 2.805 \times {\text{k}}_{\text{U}} {}^{3} + 19.48 \times {\text{k}}_{\text{U}} {}^{2} - 43.58 \times {\text{k}}_{\text{U}} + 38.11$$

As shown in FIG. 11, the curve A22, which satisfies the condition that the transmittance ratio is 0.45 or less, is located above the curve A21. The relational equation (equation of the curve A22) of the minimum film thickness of the transmittance adjusting film to satisfy the condition that the transmittance ratio is 0.45 or less is as follows.

$${\text{d}}_{\text{Umin}} = 8.592 \times {\text{k}}_{\text{U}} {}^{3} - 38.60 \times {\text{k}}_{\text{U}} {}^{2} + 54.28 \times {\text{k}}_{\text{U}} - 15.36$$

These results indicate that, when the film thickness dᵤ[nm] and the extinction coefficient kᵤ of the transmittance adjusting film satisfy

$${d}_{U} \geq - 2.805 \times {k}_{U} {}^{3} + 19.48 \times {k}_{U} {}^{2} - 43.58 \times {k}_{U} - 15.36 ,$$

the ratio of the transmittance of the exposure light transmitted through the stacked structure of the phase shift film and the transmittance adjusting film with respect to the transmittance of the exposure light transmitted through the phase shift film becomes 0.5 or less.

In addition, when the film thickness dᵤ[nm]and the extinction coefficient kᵤ of the transmittance adjusting film satisfy

$${\text{d}}_{\text{U}} \geq 8.592 \times {\text{k}}_{\text{U}} {}^{3} - 38.60 \times {\text{k}}_{\text{U}} {}^{2} + 54.28 \times {\text{k}}_{\text{U}} - 15.36 ,$$

the ratio of the transmittance of the exposure light transmitted through the stacked structure of the phase shift film and the transmittance adjusting film with respect to the transmittance of the exposure light transmitted through the phase shift film becomes 0.45 or less.

In FIG. 11, the curve A21 is above the curve B21 (curve of threshold in which the transmittance ratio is 0.50). This indicates that the transmittance adjusting film that satisfies the relationship of the equation (2) derived based on the curve A21 will have a transmittance ratio of 0.50 or less, even when the transmittance adjusting film was provided on the phase shift film used in the optical simulation B2. Similarly, the curve A22 is above the curve B22 (threshold curve in which the transmittance ratio is 0.43). This indicates that the transmittance adjusting film that satisfies the relationship of the equation (2-A22) derived based on the curve A22 has a transmittance ratio of 0.45 or less even when the transmittance adjusting film is provided on the phase shift film used in the optical simulation B2. These results indicate that the transmittance adjusting film that satisfies the relationship of the equation (2) has the above-mentioned transmittance ratio of 0.50 or less, regardless of the optical characteristics of the phase shift film provided thereunder.

Thus, the inventors found out that the transmittance adjusting film that satisfies the relationships of the equation (1) and the equation (2) has the above-mentioned increased amount in phase difference of 20 degrees or less, and the above-mentioned transmittance ratio of 0.50 or less. The present disclosure has been made as a result of the diligent study described above.

### <First Embodiment>

### [Mask Blank and Its Manufacture]

The embodiments are explained below with reference to the drawings.

FIG. 1 is a cross-sectional view showing the configuration of a mask blank 10 of the first embodiment of the present disclosure. The mask blank 10 of the present disclosure shown in FIG. 1 has a structure where a phase shift film 2, an intermediate film 3, a transmittance adjusting film 4, a light shielding film 5, a hard mask film 6, and a resist film 7 are stacked in this order on a transparent substrate 1.

The transparent substrate 1 can be made of quartz glass, aluminosilicate glass, soda-lime glass, low thermal expansion glass (SiO₂-TiO₂ glass, etc.), and the like, in addition to synthetic quartz glass. Among the above, synthetic quartz glass is particularly preferable as a material for forming the transparent substrate 1 of the mask blank for having a high transmittance to an ArF excimer laser light. The refractive index n of the material for forming the transparent substrate 1 to an ArF exposure light wavelength (about 193 nm) is preferably 1.5 or more and 1.6 or less, more preferably 1.52 or more and 1.59 or less, and even more preferably 1.54 or more and 1.58 or less.

To obtain the proper phase shift effect, it is preferable for the phase shift film 2 to be adjusted such that the phase difference generated between the transmitting ArF exposure light and the light transmitted through the air for a same distance as the thickness of the phase shift film 2 is within the range of 150 degrees or more and 210 degrees or less. A phase difference of the phase shift film 2 is preferably 155 degrees or more, and more preferably 160 degrees or more. On the other hand, a phase difference of the phase shift film 2 is preferably 195 degrees or less, and more preferably 190 degrees or less.

The phase shift film 2 preferably transmits an exposure light in the transmittance of 12% or more. In recent years, NTD (Negative Tone Development) is being used as an exposure/development process to a resist film on a semiconductor substrate (wafer), in which a bright field mask (transfer mask having a high pattern opening rate) is often used. In a bright field phase shift mask, a phase shift film having 12% or more transmittance to an exposure light provides a better balance between 0-order light and first-order light of light transmitted through a light transmitting portion. With the better balance, exposure light transmitted through the phase shift film interferes with the 0-order light to exhibit a higher reduction effect on a light intensity and improves a pattern resolution property on a resist film. To further enhance the effect of emphasizing the pattern edge of a transfer image (projected optical image) by the phase shift effect, the phase shift film 2 preferably transmits light with the transmittance of 19% or more, and more preferably, with the transmittance of 28% or more. On the other hand, the transmittance of the phase shift film 2 to an ArF exposure light is preferably 50% or less, and more preferably 40% or less. When the transmittance of the phase shift film 2 to the ArF exposure light exceeds 50%, the influence of sidelobes will become too strong and is not preferable.

The thickness of the phase shift film 2 is preferably 90 nm or less, and more preferably 80 nm or less. On the other hand, the thickness of the phase shift film 2 is preferably 40 nm or more, and more preferably 50 nm or more.

For the phase shift film 2 to satisfy the conditions regarding the optical characteristics and film thickness mentioned above, the refractive index n of the phase shift film is preferably 2.0 or more, and more preferably 2.1 or more. Further, the refractive index n of the phase shift film 2 is preferably 3.0 or less, and more preferably 2.9 or less. The extinction coefficient k of the phase shift film 2 is preferably 0.9 or less, and more preferably 0.6 or less. Further, the extinction coefficient k of the phase shift film 2 is preferably 0.1 or more.

The refractive index n and the extinction coefficient k of a thin film including the phase shift film 2 are not determined only by the composition of the thin film. Film density, crystal state, etc. of the thin film are also factors that affect the refractive index n and the extinction coefficient k. Therefore, the conditions in forming a thin film by reactive sputtering are adjusted so that the thin film has desired refractive index n and extinction coefficient k. For allowing the thin film to have the refractive index n and the extinction coefficient k within the above range, not only a ratio of mixed gas of noble gas and reactive gas (oxygen gas, nitrogen gas, etc.) is adjusted in forming the film by reactive sputtering, but various other adjustments are made upon forming the film by reactive sputtering, such as pressure in a film forming chamber, power applied to a sputtering target, and positional relationship such as distance between the target and the transparent substrate 1. These film-forming conditions are unique to film-forming apparatuses, and are adjusted properly so that the thin film to be formed has desired refractive index n and extinction coefficient k.

The phase shift film 2 is formed of a material containing a non-metallic element and silicon. A thin film formed of a material containing silicon and a transition metal tends to have a higher extinction coefficient k. To reduce the entire film thickness of the phase shift film 2, the phase shift film 2 can be formed of a material containing a non-metallic element, silicon, and a transition metal. Examples of the transition metal to be included in this case include one metal among molybdenum (Mo), tantalum (Ta), tungsten (W), titanium (Ti), chromium (Cr), hafnium (Hf), nickel (Ni), vanadium (V), zirconium (Zr), ruthenium (Ru), rhodium (Rh), zinc (Zn), niobium (Nb), palladium (Pd), etc., or an alloy of these metals. On the other hand, the phase shift film 2 is preferably formed of a material consisting of a non-metallic element and silicon, or a material consisting of a metalloid element, a non-metallic element, and silicon.

In the case of including a metalloid element in the phase shift film 2, it is preferable to include one or more metalloid elements selected from boron, germanium, antimony, and tellurium, since enhancement in conductivity of silicon to be used as a sputtering target can be expected.

In the case of including a non-metallic element in the phase shift film 2, it is preferable to include one or more non-metallic elements selected from nitrogen, oxygen, carbon, fluorine, and hydrogen. These non-metallic elements include noble gas such as helium (He), argon (Ar), krypton (Kr), and xenon (Xe).

In the overall composition of the phase shift film 2, the total content of nitrogen and oxygen is preferably 40atom% or more, and more preferably 50atom% or more.

The phase shift film 2 can be formed of a material containing a metal element and oxygen. Examples of the metal element to be included in this case include one metal among zirconium (Zr), tantalum (Ta), tungsten (W), titanium (Ti), chromium (Cr), molybdenum (Mo), hafnium (Hf), nickel (Ni), vanadium (V), ruthenium (Ru), rhodium (Rh), zinc (Zn), niobium (Nb), palladium (Pd), etc., or an alloy of these metals. In this case, the oxygen content of the phase shift film 2 is preferably 40atom% or more, and more preferably 50atom% or more.

In this embodiment, an intermediate film 3 containing silicon and oxygen is provided between the phase shift film 2 and the transmittance adjusting film 4. This intermediate film 3 functions as an etching stopper film to the phase shift film 2, and only needs to have a film thickness that functions as an etching mask until dry etching for forming a pattern in the phase shift film 2 is completed. Although not particularly limited, it is preferable that this intermediate film 3 is formed of the same material as the substrate 1. In this way, even when the exposed surface of the transparent substrate 1 is etched by an influence of etching gas during forming a pattern in the phase shift film 2 by dry etching, the intermediate film 3 is also etched by approximately the same amount. Therefore, when the phase shift pattern is formed, a preferable range of phase difference as described above can be secured between the exposure light that transmits through the exposed portion of the transparent substrate 1 and the exposure light that transmits through the phase shift film 2 (and the intermediate film 3). Thus, the mask blank of this embodiment is preferable in enhancing the reliability of the phase shift function by providing the intermediate film 3. The oxygen content of the intermediate film 3 is preferably 50atom% or more, more preferably 55atom% or more, and even more preferably 60atom% or more. The thickness of the intermediate film 3 is preferably 1 nm or more, and more preferably 2 nm or more. The thickness of the intermediate film 3 is preferably 10 nm or less, and more preferably 5 nm or less.

The mask blank 10 has a transmittance adjusting film 4 on the intermediate film 3. The transmittance adjusting film 4 satisfies both relationships according to the equation (1) and the equation (2) given below, where nᵤ is the refractive index with respect to a wavelength of the exposure light, kᵤ is the extinction coefficient with respect to a wavelength of the exposure light, and dᵤ[nm]is the thickness.

$${\text{d}}_{\text{U}} \leq - 17.63 \times {\text{n}}_{\text{U}} {}^{3} + 142.0 \times {\text{n}}_{\text{U}} {}^{2} - 364.9 \times {\text{n}}_{\text{U}} + 315.8$$

$${\text{d}}_{\text{U}} \geq - 2.805 \times {\text{k}}_{\text{U}} {}^{3} + 19.48 \times {\text{k}}_{\text{U}} {}^{2} - 43.58 \times {\text{k}}_{\text{U}} + 38.11$$

As described above, the transmittance adjusting film 4 satisfying the equation (1) can satisfy the condition that the increased amount in phase difference of the exposure light transmitted through the stacked structure of the phase shift film 2 and the transmittance adjusting film 4 with respect to the exposure light transmitted through the phase shift film 2 is 20 degrees or less. Further, the transmittance adjusting film 4 satisfying the equation (2) can satisfy the condition that the ratio of the transmittance of the exposure light transmitted through the stacked structure of the phase shift film 2 and the transmittance adjusting film 4 with respect to the transmittance of the exposure light transmitted through the phase shift film 2 is 0.50 or less.

On the above basis, the refractive index nᵤ of the transmittance adjusting film 4 is preferably 1.2 or more, and more preferably 1.5 or more. The refractive index nᵤ of the transmittance adjusting film 4 is preferably 3.0 or less, and more preferably 2.5 or less. On the other hand, the extinction coefficient kᵤ of the transmittance adjusting film 4 is preferably 1.5 or more, and more preferably 2.0 or more. Further, the extinction coefficient kᵤ of the transmittance adjusting film 4 is preferably 3.0 or less, and more preferably 2.5 or less.

The extinction coefficient kᵤ and the thickness dᵤ[nm] of the transmittance adjusting film 4 preferably satisfy the relationship according to the following equation (3).

$${\text{d}}_{\text{U}} \leq 8.646 \times {\text{k}}_{\text{U}} {}^{2} - 38.42 \times {\text{k}}_{\text{U}} + 61.89$$

The background of the derivation of the equation (3) is described. The inventors studied the condition in which, in the case where the transmittance adjusting film 4 is provided on the phase shift film 2 having the transmittance of 12% or more, the transmittance through the phase shift film 2 and the transmittance adjusting film 4 (hereafter may be referred to as transmittance of the stacked body) is 2% or more. In this study, the inventors focused on the relationship between the maximum film thickness and the extinction coefficient k of the transmittance adjusting film, and conducted the optical simulations A3 and B3 for the phase shift film and the transmittance adjusting film, respectively. In the optical simulations A3 and B3, the maximum film thickness of the transmittance adjusting film was calculated to satisfy the condition that the transmittance of the stacked body is 2% or more while changing the film thickness of the transmittance adjusting film within the extinction coefficient k ranging between 1.5 and 2.0. As for the phase shift film, the same film as in the optical simulations A1 and A2 was used in the optical simulation A3, and the same film as in the optical simulations B1 and B2 was used in the optical simulation B3.

Thereafter, based on each result of the optical simulations A3 and B3, the relationship between the extinction coefficient k and the maximum film thickness of the transmittance adjusting film was organized. FIG. 12 shows the comparison between the results of the optical simulation A3 and the optical simulation B3 regarding the relationship between the maximum film thickness and the extinction coefficient k of the transmittance adjusting film. The curves A31 and A32 in FIG. 12 show the results of the optical simulation A3, showing the maximum film thickness of the transmittance adjusting film to satisfy the condition that the transmittance of the stacked body is 2% or more, and 4% or more, respectively. The curves B31 and B32 show the results of the optical simulation B2, showing the maximum film thickness of the transmittance adjusting film to satisfy the condition that the transmittance of the stacked body is 2% or more, and 4% or more, respectively.

The relational equation (equation of the curve A31) of the maximum film thickness of the transmittance adjusting film to satisfy the condition that the transmittance of the stacked body is 2% or more is as follows.

$${\text{d}}_{\text{Umax}} = 8.646 \times {\text{k}}_{\text{U}} {}^{2} - 38.42 \times {\text{k}}_{\text{U}} + 61.89$$

As shown in FIG. 12, the curve A32, which satisfies the condition that the transmittance of the stacked body is 4% or more, is located below the curve A31. The relational equation (equation of the curve A32) of the maximum film thickness of the transmittance adjusting film to satisfy the condition that the transmittance of the stacked body is 4% or more is as follows.

$${\text{d}}_{\text{Umax}} = 5.101 \times {\text{k}}_{\text{U}} {}^{2} - 22.46 \times {\text{k}}_{\text{U}} + 38.44$$

From these results, the inventors found that when the film thickness dᵤ[nm]and the extinction coefficient kᵤ of the transmittance adjusting film satisfy

$${\text{d}}_{\text{U}} \leq 8.646 \times {\text{k}}_{\text{U}} {}^{2} - 38.42 \times {\text{k}}_{\text{U}} + 61.89 ,$$

the transmittance of the stacked body is 2% or more.

In addition, the inventors found that when the film thickness dᵤ[nm] and the extinction coefficient kᵤ of the transmittance adjusting film satisfy

$${\text{d}}_{\text{U}} \leq 5.101 \times {\text{k}}_{\text{U}} {}^{2} - 22.46 \times {\text{k}}_{\text{U}} + 38.44 ,$$

the transmittance of the stacked body is 4% or more.

In FIG. 11, the curve A31 is below the curve B31 (curve of threshold in which the transmittance of the stacked body is 2% or more). This indicates that the transmittance adjusting film that satisfies the relationship of the equation (3) derived based on the curve A31 has the transmittance of the stacked body of 2% or more even when the transmittance adjusting film is provided on the phase shift film used in the optical simulation B3. Similarly, the curve A32 is below the curve B32 (curve of threshold in which the transmittance of the stacked body is 4% or more). This indicates that the transmittance adjusting film that satisfies the relationship of the equation (3-A32) derived based on the curve A32 has the transmittance of the stacked body of 4% or more, even when the transmittance adjusting film was provided on the phase shift film used in the optical simulation B3.

These results indicate that the transmittance adjusting film that satisfies the relationship of the equation (3) has the transmittance of the stacked body of 2% or more, regardless of the optical characteristics of the phase shift film provided thereunder.

Any material may be used for the transmittance adjusting film 4 as long as the optical characteristics described above can be obtained. The transmittance adjusting film 4 preferably contains silicon, and more preferably, contains silicon and non-metallic elements. Further, the transmittance adjusting film 4 preferably contains silicon and nitrogen from the viewpoint of easier acquisition of desired characteristics. A total content of silicon and nitrogen of the transmittance adjusting film 4 is preferably 97atom% or more, and more preferably 99atom% or more.

The mask blank 10 is configured to include a light shielding film 5 on the transmittance adjusting film 4. For the light shielding film 5, it is necessary to apply a material having a sufficient etching selectivity to etching gas used in forming a pattern in the transmittance adjusting film 4. The light shielding film 5 in this case is preferably formed of a material containing chromium. As for materials containing chromium for forming the light shielding film 5, materials containing chromium and one or more elements selected from oxygen, nitrogen, carbon, boron, and fluorine can be given in addition to chromium metal.

While a chromium-based material is generally etched by mixed gas of chlorine-based gas and oxygen gas, an etching rate of a chromium metal with respect to the etching gas is not so high. Considering enhancing an etching rate with respect to etching gas as mixed gas of chlorine-based gas and oxygen gas, a material for forming the light shielding film 5 preferably contains chromium and one or more elements selected from oxygen, nitrogen, carbon, boron, and fluorine. Further, one or more elements among molybdenum, indium, and tin can be included in the material containing chromium for forming the light shielding film 5. Including one or more elements among molybdenum, indium, and tin can further increase an etching rate to mixed gas of chlorine-based gas and oxygen gas.

On the other hand, the light shielding film 5 can have a structure where a layer consisting of a material containing chromium and a layer consisting of a material containing silicon are stacked in this order from the transmittance adjusting film 4 side. Specific matters on the material containing chromium in this case are the same as those in the case of the light shielding film 5 described above.

The mask blank 10 is preferably configured to have a hard mask film 6 further stacked on the light shielding film 5, the hard mask film 6 formed of a material having an etching selectivity to etching gas used in etching the light shielding film 5. Since the hard mask film 6 is basically not restricted by an optical density, the thickness of the hard mask film 6 can be reduced significantly compared to the thickness of the light shielding film 5. A resist film 7 of an organic material only requires a film thickness to function as an etching mask until dry etching for forming a pattern in the hard mask film 6 is completed. Therefore, the thickness of the resist film 7 can be reduced significantly compared to conventional cases. Reduction of the film thickness of the resist film 7 is effective for enhancing resist resolution and preventing collapse of pattern, which is extremely important in facing the requirements for miniaturization.

In the case where the light shielding film 5 is formed of a material containing chromium, the hard mask film 6 is preferably formed of a material containing silicon. The hard mask film 6 in this case tends to have low adhesiveness with a resist film of an organic material. Therefore, it is preferable to treat the surface of the hard mask film 6 with HMDS (Hexamethyldisilazane) to enhance surface adhesiveness. The hard mask film 6 in this case is more preferably formed of SiO₂, SiN, SiON, etc.

Further, in the case where the light shielding film 5 is formed of a material containing chromium, materials containing tantalum are also applicable as materials of the hard mask film 6, in addition to the materials given above. The material containing tantalum in this case includes, in addition to tantalum metal, a material containing tantalum and one or more elements selected from nitrogen, oxygen, boron, and carbon, for example, Ta, TaN, TaO, TaON, TaBN, TaBO, TaBON, TaCN, TaCO, TaCON, TaBCN, TaBOCN, etc. Further, in the case where the light shielding film 5 is formed of a material containing silicon, the hard mask film 6 is preferably formed of the material containing chromium given above.

In the mask blank 10, a resist film 7 of an organic material is preferably formed with the film thickness of 100 nm or less in contact with a surface of the hard mask film 6. In the case of a fine pattern to meet DRAM hp32nm generation, a SRAF (Sub-Resolution Assist Feature) with 40 nm line width may be provided in a transfer pattern (phase shift pattern) to be formed in the hard mask film 6. However, even in this case, the cross-sectional aspect ratio of the resist pattern can be reduced to 1:2.5 so that collapse and peeling of the resist pattern can be prevented in developing, rinsing, etc. of the resist film 7. The resist film 7 preferably has the film thickness of 80 nm or less. In the case where the hard mask film 6 is formed of a material containing silicon, it is preferable to conduct a sylilation treatment using HMDS (Hexamethyldisilazane), etc. on the surface of the hard mask film 6 before forming the resist film.

While the phase shift film 2, the intermediate film 3, the transmittance adjusting film 4, the light shielding film 5, and the hard mask film 6 are formed by the sputtering method, any sputtering method is applicable such as DC sputtering method, RF sputtering method, and ion beam sputtering method. In the case where the target has low conductivity, application of the RF sputtering method and ion beam sputtering method is preferable. Application of the RF sputtering method is preferable, considering the film-forming rate. Further, the resist film 7 is formed by the spin coating method.

While the configuration of the mask blank 10 of this embodiment was explained referring to FIG. 1, the configuration is not limited thereto, but the mask blank can be configured, for example, without the intermediate film 3, the hard mask film 6, and the resist film 7. The mask blank can be configured with an etching stopper film provided between the substrate 1 and the phase shift film 2. Examples of materials of the etching stopper film in this case include a material containing aluminum, silicon, and oxygen, a material containing aluminum, hafnium, and oxygen, a material containing hafnium and oxygen, and/or a material containing chromium. These points are the same in the mask blank of the second embodiment described below.

### [Phase Shift Mask and Its Manufacture]

The phase shift mask 100 (see FIG. 2) according to the first embodiment includes a phase shift film (phase shift pattern) 2a having a first pattern on a transparent substrate 1, and a transmittance adjusting film (transmittance adjusting pattern) 4b having a second pattern on the phase shift pattern 2a. In addition, an intermediate film (intermediate pattern) 3b having a second pattern is provided between the phase shift pattern 2a and the transmittance adjusting pattern 4b. Further, a light shielding film (light shielding pattern) 5c having a third pattern is provided on the transmittance adjusting film 4b.

In other words, the phase shift mask 100 according to the first embodiment includes a phase shift pattern 2a on the transparent substrate 1; an intermediate pattern 3b, a transmittance adjusting pattern 4b, and a light shielding pattern 5c on the phase shift pattern 2a; the phase shift pattern 2a generates a phase difference of 150 degrees or more and 210 degrees or less between an ArF excimer laser exposure light transmitted through the phase shift pattern 2a and the exposure light transmitted through the air for a same distance as the thickness of the phase shift pattern 2a; and the refractive index nᵤ with respect to a wavelength of the exposure light, the extinction coefficient kᵤ with respect to the wavelength of the exposure light, and the thickness dᵤ[nm]of the transmittance adjusting pattern 4b satisfy the following equations (1) and (2) .

$${\text{d}}_{\text{U}} \leq - 17.63 \times {\text{n}}_{\text{U}} {}^{3} + 142.0 \times {\text{n}}_{\text{U}} {}^{2} - 364.9 \times {\text{n}}_{\text{U}} + 315.8$$

$${\text{d}}_{\text{U}} \geq - 2.805 \times {\text{k}}_{\text{U}} {}^{3} + 19.48 \times {\text{k}}_{\text{U}} {}^{2} - 43.58 \times {\text{k}}_{\text{U}} + 38.11$$

Specific configurations of the transparent substrate 1, the phase shift pattern 2a, the intermediate pattern 3b, the transmittance adjusting pattern 4b, and the light shielding pattern 5c of the phase shift mask 100 are the same as those of the mask blank 10.

The method of manufacturing the phase shift mask 100 of the first embodiment is explained below according to the manufacturing steps shown in FIGS. 3A-3D and 4A-4D showing schematic cross-sectional views of the principal part.

A first pattern to be formed in the phase shift film 2 is written with an electron beam on the resist film 7 formed on the mask blank 10 shown in FIG. 1 by the spin coating method, and predetermined treatments such as developing are further conducted to thereby form a resist film (resist pattern) 7a having a first pattern (see FIG. 3A). The first pattern includes a phase shift pattern formed in the phase shift film 2 to exhibit the phase shift effect, and a pattern for an alignment mark (left opening in FIG. 2).

Subsequently, dry etching using fluorine-based gas is conducted on the hard mask film 6 with the first resist pattern 7a as a mask, and a hard mask film (hard mask pattern) 6a having a first pattern is formed (see FIG. 3B).

Next, using the first resist pattern 7a and the hard mask pattern 6a as masks, dry etching using mixed gas of chlorine-based gas and oxygen-based gas is conducted on the light shielding film 5 to form a light shielding film (light shielding pattern) 5a having a first pattern (see FIG. 3C). Subsequently, the first resist pattern 7a is removed and a cleaning process is conducted, dry etching using fluorine-based gas is conducted on the transmittance adjusting film 4, the intermediate film 3, and the phase shift film 2 with the light shielding pattern 5a and the hard mask pattern 6a as masks, and a transmittance adjusting film (transmittance adjusting pattern) 4a having a first pattern, an intermediate film (intermediate pattern) 3a having a first pattern, and a phase shift film (phase shift pattern) 2a′ partially having a first pattern are formed (see FIG. 3D). The hard mask pattern 6a is removed by this dry etching. In the dry etching of the phase shift film 2, it is preferable to adjust the thickness of the remaining portion of the phase shift film 2a′ so that the remaining portion of the phase shift film 2a′ is substantially concurrently removed upon completion of forming the transmittance adjusting pattern 4b in the process of forming the transmittance adjusting pattern 4b in the transmittance adjusting film 4 by dry etching which is described later.

Next, a resist film is formed by the spin coating method. Thereafter, a pattern which should be formed in the transmittance adjusting film 4 is written with an electron beam on the resist film, and predetermined treatments such as developing are further conducted to thereby form a resist film (resist pattern) 8b having a second pattern (see FIG. 4A). Next, dry etching is conducted on the light shielding film 5a using mixed gas of chlorine-based gas and oxygen gas with the resist pattern 8b as a mask, and a light shielding film (light shielding pattern 5b) having a second pattern is formed (see FIG. 4A).

Subsequently, the resist pattern 8b is removed and a cleaning process is conducted, dry etching using fluorine-based gas is conducted on the transmittance adjusting film 4 with the light shielding pattern 5b as a mask, and a transmittance adjusting film (transmittance adjusting pattern) 4b having a second pattern is formed (see FIG. 4B). At this stage, the exposed remaining portion of the phase shift film (phase shift pattern) 2a′ that partially has the first pattern is also removed, and the phase shift film (phase shift pattern) 2a′ having a first pattern is formed (see FIG. 4B).

Next, dry etching (over-etching) using fluorine-based gas is conducted on the intermediate pattern 3a with the light shielding pattern 5b and the transmittance adjusting pattern 4b as masks, and an intermediate film (intermediate pattern) 3b having a second pattern is formed (see FIG. 4C). At this stage, an exposed portion of the transparent substrate 1 may be dug by fluorine-based gas, but a desired phase difference can be secured between the exposed portion of the transparent substrate 1 and exposed portion of the phase shift pattern 2a since the intermediate film 3 is formed of the material equivalent to that of the transparent substrate 1 as described above.

Next, a resist film is formed by the spin coating method. Thereafter, a pattern which should be formed in the light shielding film 5 is written with an electron beam on the resist film, and predetermined treatments such as developing are further conducted to thereby form a resist film (resist pattern) 9c having a third pattern (see FIG. 4D). Next, dry etching is conducted on the light shielding pattern 5b using mixed gas of chlorine-based gas and oxygen gas with the resist pattern 9c as a mask, and a light shielding film (light shielding pattern) 5c having a third pattern is formed (see FIG. 4D).

Thereafter, the resist pattern 9c is removed and a cleaning step is conducted. The phase shift mask 100 shown in FIG. 2 can thus be formed.

### [Manufacture of Semiconductor Device]

In the method of manufacturing a semiconductor device according to the first embodiment, a transfer pattern is transferred to a resist film on a semiconductor substrate by exposure using the phase shift mask 100 of the first embodiment or the phase shift mask 100 manufactured by using the mask blank 10 of the first embodiment. Therefore, when transfer is made on a resist film on a semiconductor device by exposure using the phase shift mask 100 of the first embodiment, a pattern can be formed in the resist film on the semiconductor device with a precision sufficiently satisfying the design specification.

### <Second Embodiment>

### [Mask Blank and Its Manufacture]

FIG. 5 is a cross-sectional view showing a configuration of a mask blank 20 according to the second embodiment of the present disclosure. The mask blank 20 shown in FIG. 5 differs from the mask blank 10 shown in FIG. 1 in that a phase shift film 15 is configured from a trilayer structure where a first layer 12, a second layer 13, and a third layer 14 are stacked, and that a transmittance adjusting film 16 is provided on the phase shift film 15. Explanation is arbitrarily omitted hereafter on the points that are common to the mask blank 10 of the first embodiment.

The phase shift film 15 of this embodiment is configured such that the refractive indexes n₁, n₂, and n₃ of the first layer 12, the second layer 13, and the third layer 14, respectively, with respect to the wavelength of an ArF exposure light satisfy the relationship of n₁>n₂>n₃; and the extinction coefficients k₁, k₂, and k₃ of the first layer 12, the second layer 13, and the third layer 14, respectively, satisfy the relationship of k₁>k₂>k₃. In addition, the film thicknesses d₁, d₂, and d₃ of the first layer 12, the second layer 13, and the third layer 14, respectively, satisfy the relationship of d₁>d₂>d₃.

The phase shift film 15 is configured from the first layer 12, the second layer 13, and the third layer 14 satisfying these relationships, and thus, a phase shift film can be formed which has a higher transmittance than that of the phase shift film 2 of the first embodiment. The configuration of this phase shift film 15 includes the conditions of the phase shift film set upon simulation of the optical simulations B1, B2, and B3.

The materials configuring the phase shift film 15 can be the same as those of the phase shift film 2 of the first embodiment. In the overall composition of the phase shift film 15, a total content of nitrogen and oxygen is preferably 40atom% or more, and more preferably 50atom% or more.

The first layer 12 is preferably formed of a material containing silicon and nitrogen, the second layer 13 is preferably formed of a material containing silicon, oxygen, and nitrogen, and the third layer 14 as an uppermost layer is preferably formed of a material containing silicon and oxygen.

The transmittance adjusting film 16 is stacked on the phase shift film 15, which is a point that is different from the transmittance adjusting film 4 in the first embodiment. Other conditions that should be satisfied are the same as those of the transmittance adjusting film 4 in the first embodiment.

As mentioned above, the mask blank 20 of this embodiment has the transmittance adjusting film 16 on the phase shift film 15. The transmittance adjusting film 16 satisfies both relationships according to the equation (1) and the equation (2) given below, where nᵤ is the refractive index with respect to a wavelength of the exposure light, kᵤ is the extinction coefficient with respect to the wavelength of the exposure light, and dᵤ[nm]is the thickness.

$${\text{d}}_{\text{U}} \leq - 17.63 \times {\text{n}}_{\text{U}} {}^{3} + 142.0 \times {\text{n}}_{\text{U}} {}^{2} - 364.9 \times {\text{n}}_{\text{U}} + 315.8$$

$${\text{d}}_{\text{U}} \geq - 2.805 \times {\text{k}}_{\text{U}} {}^{3} + 19.48 \times {\text{k}}_{\text{U}} {}^{2} - 43.58 \times {\text{k}}_{\text{U}} + 38.11$$

As described above, the transmittance adjusting film 16 satisfying the equation (1) can satisfy the condition that the increased amount in phase difference of the exposure light transmitted through the stacked structure of the phase shift film 15 and the transmittance adjusting film 16 with respect to the exposure light transmitted through the phase shift film 15 is 20 degrees or less. Further, the transmittance adjusting film 16 satisfying the equation (2) can satisfy the condition that the ratio of the transmittance of the exposure light transmitted through the stacked structure of the phase shift film 15 and the transmittance adjusting film 16 with respect to the transmittance of the exposure light transmitted through the phase shift film 15 is 0.50 or less.

### [Phase Shift Mask and Its Manufacture]

The phase shift mask 200 (see FIG. 6) according to the second embodiment includes a phase shift film (phase shift pattern) 15a having a first pattern on the transparent substrate 1, and a transmittance adjusting film (transmittance adjusting pattern) 16b having a second pattern on the phase shift pattern 15a. In addition, this phase shift pattern 15a has a third layer 14a having a first pattern as an uppermost layer containing silicon and oxygen on the surface that is opposite to the transparent substrate 1 side. Further, a light shielding film (light shielding pattern) 5c having a third pattern is provided on the transmittance adjusting pattern 16b.

In other words, the phase shift mask 200 according to the second embodiment includes a phase shift pattern 15a on the transparent substrate 1; a transmittance adjusting pattern 16b and a light shielding pattern 5c on the phase shift pattern 15a; the phase shift pattern 15a generates a phase difference of 150 degrees or more and 210 degrees or less between an ArF excimer laser exposure light transmitted through the phase shift pattern 15a and the exposure light transmitted through the air for a same distance as the thickness of the phase shift pattern 15a; and the refractive index nᵤ with respect to a wavelength of the exposure light, the extinction coefficient kᵤ with respect to the wavelength of the exposure light, and the thickness dᵤ[nm] of the transmittance adjusting pattern 16b satisfy the following equations (1) and (2).

$${\text{d}}_{\text{U}} \leq - 17.63 \times {\text{n}}_{\text{U}} {}^{3} + 142.0 \times {\text{n}}_{\text{U}} {}^{2} - 364.9 \times {\text{n}}_{\text{U}} + 315.8$$

$${\text{d}}_{\text{U}} \geq - 2.805 \times {\text{k}}_{\text{U}} {}^{3} + 19.48 \times {\text{k}}_{\text{U}} {}^{2} - 43.58 \times {\text{k}}_{\text{U}} + 38.11$$

Specific configurations of the transparent substrate 1, the phase shift pattern 15a, the transmittance adjusting pattern 16b, and the light shielding pattern 5c of the phase shift mask 200 are the same as those of the mask blank 20.

The method of manufacturing the phase shift mask 200 of the second embodiment is explained below according to the manufacturing steps shown in FIGS. 7A-7D and 8A-8C showing schematic cross-sectional views of the principal part.

A first pattern to be formed in the phase shift film 15 is written with an electron beam on a resist film 7 formed on the mask blank 20 shown in FIG. 5 by the spin coating method, and predetermined treatments such as developing are further conducted to thereby form a resist film (resist pattern) 7a having a first pattern (see FIG. 7A). The first pattern includes a phase shift pattern formed in the phase shift film 15 to exhibit the phase shift effect, and a pattern for an alignment mark (left opening in FIG. 6).

Subsequently, dry etching using fluorine-based gas is conducted on the hard mask film 6 with the first resist pattern 7a as a mask, and a hard mask film (hard mask pattern) 6a having a first pattern is formed (see FIG. 7B).

Next, dry etching using mixed gas of chlorine-based gas and oxygen-based gas is conducted on the light shielding film 5 with the first resist pattern 7a and the hard mask pattern 6a as masks to form a light shielding film (light shielding pattern) 5a having a first pattern (see FIG. 7C). Subsequently, the first resist pattern 7a is removed and a cleaning process is conducted, dry etching using fluorine-based gas is conducted on the transmittance adjusting film 16 and the phase shift film 15 with the light shielding pattern 5a and the hard mask pattern 6a as masks, and a transmittance adjusting film (transmittance adjusting pattern) 16a having a first pattern and a phase shift film (phase shift pattern) 15a′ partially having a first pattern are formed (see FIG. 7D). This phase shift pattern 15a′ is configured from a first layer 12a′ partially having a first pattern, a second layer 13a having a first pattern, and a third layer 14a having a first pattern. The hard mask pattern 6a is removed by this dry etching. In the dry etching of the phase shift film 15, it is preferable to adjust the thickness of the remaining portion of the phase shift film 15a′ (first layer 12a′) so that the remaining portion of the phase shift film 15a′ (first layer 12a′) is substantially concurrently removed upon completion of the transmittance adjusting pattern 16b in the process of forming the transmittance adjusting pattern 16b in the transmittance adjusting film 16 by dry etching which is described later.

Next, a resist film is formed by the spin coating method. Thereafter, a pattern which should be formed in the transmittance adjusting film 16 is written with an electron beam on the resist film, and predetermined treatments such as developing are further conducted to thereby form a resist film (resist pattern) 8b having a second pattern (see FIG. 8A). Next, dry etching is conducted using mixed gas of chlorine-based gas and oxygen gas on the light shielding film 5a with the resist pattern 8b as a mask, and a light shielding film (light shielding pattern 5b) having a second pattern is formed (see FIG. 8A).

Subsequently, the resist pattern 8b is removed and a cleaning process is conducted, dry etching using fluorine-based gas is conducted on the transmittance adjusting film 16 with the light shielding pattern 5b as a mask, and a transmittance adjusting film (transmittance adjusting pattern) 16b having a second pattern is formed (see FIG. 8B). At this stage, the exposed remaining portion of the phase shift film (phase shift pattern) 15a′ that partially includes the first pattern is also removed, and the phase shift film (phase shift pattern) 15a having the first pattern, is formed (see FIG. 8B).

Next, a resist film is formed by the spin coating method. Thereafter, a pattern which should be formed in the light shielding film 5 is written with an electron beam on the resist film, and predetermined treatments such as developing are further conducted to thereby form a resist film (resist pattern) 9c having a third pattern (see FIG. 8C). Thereafter, dry etching using mixed gas of chlorine-based gas and oxygen gas is conducted on the light shielding pattern 5b with the resist pattern 9c as a mask, and a light shielding film (light shielding pattern) 5c having a third pattern is formed (see FIG. 8C).

Thereafter, the resist pattern 9c is removed and a cleaning step is conducted. The phase shift mask 200 shown in FIG. 6 can thus be formed.

[Manufacture of Semiconductor Device]

In the method of manufacturing a semiconductor device according to the second embodiment, a transfer pattern is transferred to a resist film on a semiconductor substrate by exposure using the phase shift mask 200 of the second embodiment or the phase shift mask 200 manufactured by using the mask blank 20 of the second embodiment. Therefore, when transfer is made on a resist film on a semiconductor device by exposure using the phase shift mask 200 of the second embodiment, a pattern can be formed in the resist film on the semiconductor device with a precision sufficiently satisfying the design specification.

### <Third Embodiment>

### [Mask Blank and Its Manufacture]

FIG. 13 is a cross-sectional view showing a configuration of a mask blank 30 of the third embodiment of the present disclosure. The mask blank 30 of FIG. 13 differs from the mask blank 10 of FIG. 1 in that a transmittance adjusting film 41 is provided directly on a phase shift film 2 and that an etching stopper film 31 is provided between the transmittance adjusting film 41 and a light shielding film 5. Explanation is arbitrarily omitted hereafter on the points that are common to the mask blank 10 of the first embodiment.

The transmittance adjusting film 41 of this embodiment is formed of a material containing chromium. Since the transmittance adjusting film 41 has sufficient etching selectivity with the phase shift film 2, a film that corresponds to the intermediate film 3 in the first embodiment is not provided. The transmittance adjusting film 41 is preferably formed of a material containing chromium and one or more elements selected from oxygen, nitrogen, carbon, boron, and fluorine. The transmittance adjusting film 41 can include the chromium-based material used in the light shielding film 5. The refractive index nᵤ with respect to a wavelength of the exposure light, the extinction coefficient kᵤ with respect to the wavelength of the exposure light, and the thickness dᵤ[nm] of the transmittance adjusting film 41 are designed to satisfy both relationships according to the equation (1) and the equation (2) .

In the case where the light shielding film 5 is formed of the material containing chromium, the etching stopper film 31 in this embodiment functions as an etching stopper when the light shielding film 5 is patterned by dry etching. The etching stopper film 31 can include a material containing silicon. The etching stopper film 31 is preferably formed of a material containing silicon and oxygen. On the other hand, the etching stopper film 31 can be formed of a material containing tantalum and oxygen. The thickness of the etching stopper film 31 is preferably 1 nm or more, and more preferably 2 nm or more. The thickness of the etching stopper film 31 is preferably 10 nm or less, and more preferably 5 nm or less. In this embodiment, there is no need to provide the etching stopper film 31 when the light shielding film 5 is formed of a material containing silicon or a material containing tantalum.

As mentioned above, the mask blank 30 of this embodiment has the transmittance adjusting film 41 on the phase shift film 2. The transmittance adjusting film 41 satisfies both relationships according to the equation (1) and the equation (2) given below, where nᵤ is the refractive index with respect to a wavelength of the exposure light, kᵤ is the extinction coefficient with respect to the wavelength of the exposure light, and dᵤ[nm] is the thickness.

$${\text{d}}_{\text{U}} \leq - 17.63 \times {\text{n}}_{\text{U}} {}^{3} + 142.0 \times {\text{n}}_{\text{U}} {}^{2} - 364.9 \times {\text{n}}_{\text{U}} + 315.8$$

$${\text{d}}_{\text{U}} \geq - 2.805 \times {\text{k}}_{\text{U}} {}^{3} + 19.48 \times {\text{k}}_{\text{U}} {}^{2} - 43.58 \times {\text{k}}_{\text{U}} + 38.11$$

As described above, the transmittance adjusting film 41 satisfying the equation (1) can satisfy the condition that the increased amount in phase difference of the exposure light transmitted through the stacked structure of the phase shift film 2 and the transmittance adjusting film 41 with respect to the exposure light transmitted through the phase shift film 2 is 20 degrees or less. Further, the transmittance adjusting film 41 satisfying the equation (2) can satisfy the condition that the ratio of the transmittance of the exposure light transmitted through the stacked structure of the phase shift film 2 and the transmittance adjusting film 41 with respect to the transmittance of the exposure light transmitted through the phase shift film 2 is 0.50 or less.

### [Phase Shift Mask and Its Manufacture]

The phase shift mask 300 (see FIG. 14) according to the third embodiment includes a phase shift film (phase shift pattern) 2a having a first pattern on the transparent substrate 1, and a transmittance adjusting film (transmittance adjusting pattern) 41b having a second pattern on the phase shift pattern 2a. Further, an etching stopper film (etching stopper pattern) 31b having a second pattern is provided on the transmittance adjusting pattern 41b. A light shielding film (light shielding pattern) 5c having a third pattern is provided on the etching stopper film 31b.

In other words, the phase shift mask 300 according to the third embodiment includes a phase shift pattern 2a on the transparent substrate 1; a transmittance adjusting pattern 41b, an etching stopper pattern 31b, and a light shielding pattern 5c on the phase shift pattern 2a; the phase shift pattern 2a generates a phase difference of 150 degrees or more and 210 degrees or less between an ArF excimer laser exposure light transmitted through the phase shift pattern 2a and the exposure light transmitted through the air for a same distance as the thickness of the phase shift pattern 2a; and the refractive index nᵤ with respect to a wavelength of the exposure light, the extinction coefficient kᵤ with respect to the wavelength of the exposure light, and the thickness dᵤ[nm]of the transmittance adjusting pattern 41b satisfy the following equations (1) and (2) .

$${\text{d}}_{\text{U}} \leq - 17.63 \times {\text{n}}_{\text{U}} {}^{3} + 142.0 \times {\text{n}}_{\text{U}} {}^{2} - 364.9 \times {\text{n}}_{\text{U}} + 315.8$$

$${\text{d}}_{\text{U}} \geq - 2.805 \times {\text{k}}_{\text{U}} {}^{3} + 19.48 \times {\text{k}}_{\text{U}} {}^{2} - 43.58 \times {\text{k}}_{\text{U}} + 38.11$$

Specific configurations of the transparent substrate 1, the phase shift pattern 2a, the transmittance adjusting pattern 41b, the etching stopper pattern 31b, and the light shielding pattern 5c of the phase shift mask 300 are the same as those of the mask blank 30.

The method of manufacturing the phase shift mask 300 of the third embodiment is explained below according to the manufacturing steps shown in FIGS. 15A-15D and 16A-16D showing schematic cross-sectional views of the principal part.

A first pattern to be formed in the phase shift film 2 is written with an electron beam on a resist film 7 formed on the mask blank 30 shown in FIG. 13 by the spin coating method, and predetermined treatments such as developing are further conducted to thereby form a resist film (resist pattern) 7a having a first pattern (see FIG. 15A). The first pattern includes a phase shift pattern to be formed in the phase shift film 2 to exhibit the phase shift effect.

Subsequently, dry etching using mixed gas of chlorine-based gas and oxygen gas is conducted on the light shielding film 5 with the first resist pattern 7a as a mask to form a light shielding film (light shielding pattern) 5a having the first pattern (see FIG. 15B).

Next, dry etching using fluorine-based gas is conducted on the etching stopper film 31 with the first resist pattern 7a and the light shielding pattern 5a as masks, and an etching stopper film (etching stopper pattern) 31a having the first pattern is formed (see FIG. 15C). Next, the first resist pattern 7a is removed and a cleaning process is conducted. Next, a resist film is formed by the spin coating method. Thereafter, a pattern which should be formed in the etching stopper film 31 and the transmittance adjusting film 41 is written with an electron beam on the resist film, and predetermined treatments such as developing are further conducted to thereby form a resist film (resist pattern) 8b having a second pattern (see FIG. 15D).

Next, dry etching is conducted using mixed gas of chlorine-based gas and oxygen gas on the light shielding film 5a with the resist pattern 8b as a mask, and a light shielding film (light shielding pattern 5b) having a second pattern is formed (see FIG. 16A). At this stage, dry etching with the etching stopper pattern 31a as a mask is conducted on the transmittance adjusting film 41, and a transmittance adjusting film (transmittance adjusting pattern) 41a having a first pattern is formed. Next, the second resist pattern 8b is removed and a cleaning process is conducted. Subsequently, dry etching using fluorine-based gas is conducted on the phase shift film 2 with the transmittance adjusting pattern 41a as a mask, and a phase shift film (phase shift pattern) 2a having a first pattern is formed (see FIG. 16B). At this stage, dry etching is conducted on the etching stopper pattern 31a with the light shielding pattern 5b as a mask, and an etching stopper film (etching stopper pattern) 31b having a second pattern is formed.

Next, the second resist pattern 8b is removed and a cleaning process is conducted. Subsequently, a resist film is formed by the spin coating method. Thereafter, a pattern which should be formed in the light shielding film 5 is written with an electron beam on the resist film, and predetermined treatments such as developing are further conducted to thereby form a resist film (resist pattern) 9c having a third pattern (see FIG. 16C). Next, dry etching using mixed gas of chlorine-based gas and oxygen gas is conducted on the light shielding film 5b with the resist pattern 9c as a mask, and a light shielding film (light shielding pattern 5c) having a third pattern is formed (see FIG. 16D). At this stage, dry etching is conducted on the transmittance adjusting pattern 41a with the etching stopper pattern 31b as a mask, and a transmittance adjusting film (transmittance adjusting pattern) 41b having a second pattern is formed. Thereafter, the resist pattern 9c is removed and a cleaning step is conducted. The phase shift mask 300 shown in FIG. 14 can thus be formed.

### [Manufacture of Semiconductor Device]

In the method of manufacturing a semiconductor device according to the third embodiment, a transfer pattern is transferred to a resist film on a semiconductor substrate by exposure using the phase shift mask 300 of the third embodiment or the phase shift mask 300 manufactured by using the mask blank 30 of the third embodiment. Therefore, when transfer is made on a resist film on a semiconductor device by exposure using the phase shift mask 300 of the third embodiment, a pattern can be formed in the resist film on the semiconductor device with a precision sufficiently satisfying the design specification.

### [EXAMPLES]

The embodiments of the present disclosure are described in greater detail below together with examples.

### (Example 1)

### [Manufacture of Mask Blank]

A transparent substrate 1 formed of a synthetic quartz glass with a size of main surfaces of about 152 mm x about 152 mm and a thickness of about 6.35 mm was prepared. End surfaces and main surfaces of the transparent substrate 1 were polished to a predetermined surface roughness, and thereafter subjected to predetermined cleaning treatment and drying treatment. The optical characteristics of the transparent substrate 1 were measured, and the refractive index n was 1.556 and the extinction coefficient k was 0.00 with respect to a wavelength of the ArF exposure light.

Next, the transparent substrate 1 was placed in a film forming sputtering apparatus, and by reactive sputtering using a silicon (Si) target with mixed gas of argon (Ar) gas and nitrogen (N₂) as sputtering gas, a phase shift film 2 consisting of silicon and nitrogen (SiN film Si:N=34.8atom%:65.2atom%) was formed with a thickness of 60.4 nm in contact with the surface of the transparent substrate 1. Subsequently, by reactive sputtering using a silicon (Si) target with mixed gas of argon (Ar) and oxygen (O₂) as sputtering gas, an intermediate film 3 consisting of silicon and oxygen (SiO₂ film) was formed with a thickness of 3.0 nm on the phase shift film 2. Then, by reactive sputtering using mixed gas of argon (Ar) and nitrogen (N₂) as sputtering gas, a transmittance adjusting film 4 consisting of silicon and nitrogen was formed with a thickness of 12.0 nm.

The transmittance and the phase difference of a phase shift film that was formed similarly on another transparent substrate to a light of 193 nm wavelength were measured using a phase shift measurement apparatus (MPM193 manufactured by Lasertec), and the transmittance was 18.6% and the phase difference was 180.0 degrees. The transmittance and the phase difference of a phase shift film and a transmittance adjusting film that were formed similarly on another transparent substrate to a light of 193 nm wavelength were measured, and the transmittance was 6.1% and the phase difference was 180.0 degrees. Since the intermediate film 3 has a thin film thickness of 3 nm and has high transmittance similar to that of the transparent substrate, influence of the presence/absence of the intermediate film 3 to the transmittance and phase difference is negligible.

Moreover, the optical characteristics of the phase shift film 2, the intermediate film 3, and the transmittance adjusting film 4 were measured, and the phase shift film 2 had the refractive index n of 2.61 and the extinction coefficient k of 0.36, the intermediate film 3 had the refractive index n of 1.56 and the extinction coefficient k of 0.00, and the transmittance adjusting film 4 had the refractive index nᵤ of 1.52 and the extinction coefficient kᵤ of 2.09.

These values of the film thickness dᵤ [nm] , the refractive index nᵤ, and the extinction coefficient kᵤ of the transmittance adjusting film 4 satisfy all relationships according to the equation (1), the equation (2), and the equation (3).

Next, the transparent substrate 1 having the phase shift film 2, the intermediate film 3, and the transmittance adjusting film 4 formed thereon was placed in a film forming sputtering apparatus, and by reactive sputtering using a chromium (Cr) target with mixed gas of argon (Ar), carbon dioxide (CO₂) , and helium (He) as sputtering gas, a light shielding film 5 consisting of CrOC was formed with a thickness of 44 nm on the transmittance adjusting film 4. The optical density (OD) to a light of 193 nm wavelength of the stacked structure of the phase shift film 2, the intermediate film 3, the transmittance adjusting film 4, and the light shielding film 5 was measured, and the value was 3.0 or more.

Next, on the transparent substrate 1 having the light shielding film 5 formed thereon, by reactive sputtering using silicon (Si) target and mixed gas of argon (Ar), oxygen (O₂) , and nitrogen (N₂) as sputtering gas, a hard mask film 6 consisting of silicon, nitrogen, and oxygen was formed with a thickness of 12 nm on the light shielding film 5. Then, the surface of the hard mask film 6 was subjected to a HMDS treatment. Subsequently, a resist film 7 of a chemically amplified resist for electron beam writing was formed with a film thickness of 80 nm in contact with the surface of the hard mask film 6 by the spin coating method.

Through the above procedures, a mask blank 10 having a structure where the phase shift film 2, the intermediate film 3, the transmittance adjusting film 4, the light shielding film 5, the hard mask film 6, and the resist film 7 are stacked on the transparent substrate 1 was manufactured.

### [Manufacture of Phase Shift Mask]

Next, a phase shift mask 100 of Example 1 was manufactured in accordance with the manufacturing method of the phase shift mask described in Embodiment 1, using the mask blank 10 of Example 1.

The manufactured half tone phase shift mask 100 of Example 1 was set on a mask stage of an exposure apparatus using an ArF excimer laser as an exposure light, an ArF exposure light was irradiated from the transparent substrate 1 side of the phase shift mask 100, and a pattern was transferred to a resist film on a semiconductor device by exposure. This transfer pattern included a relatively fine pattern and a relatively sparse pattern.

The resist film after the transfer by exposure was subjected to predetermined treatments to form a resist pattern, and the resist pattern was observed using an SEM (Scanning Electron Microscope). As a result, it was discovered that desired transfer patterns were formed for all patterns. From this result, it can be considered that a circuit pattern can be formed with high precision on a semiconductor device with the resist pattern as a mask.

### (Example 2)

### [Manufacture of Mask Blank]

The mask blank 20 of Example 2 was manufactured in the same manner as the mask blank 10 of Example 1, except for that the phase shift film 15 is configured from a trilayer structure where a first layer 12, a second layer 13, and a third layer 14 are stacked, and that a transmittance adjusting film 16 is provided on the phase shift film 15. Specifically, in the mask blank 20 of Example 2, the first layer 12a of the phase shift film 15 is formed with a film thickness of 41 nm and with a material consisting of silicon and nitrogen and having the refractive index n of 2.61 and the extinction coefficient k of 0.36 to a light of 193 nm wavelength; the second layer 13a is formed with a film thickness of 24 nm and with a material consisting of silicon, oxygen, and nitrogen and having the refractive index n of 2.18 and the extinction coefficient k of 0.12 to a light of 193 nm wavelength; and the third layer 14a is formed with a film thickness of 4 nm and with a material consisting of silicon and oxygen and having the refractive index n of 1.56 and the extinction coefficient k of 0.00 to a light of 193 nm wavelength. The transmittance adjusting film 16 was formed with the film thickness dᵤ of 11.7 nm and with a material consisting of silicon and nitrogen and having the refractive index nᵤ of 1.52 and the extinction coefficient kᵤ of 2.09 to a light of 193 nm wavelength. Therefore, the materials and manufacturing methods of the light shielding film 5, the hard mask film 6, and the resist film 7 are the same as those in Example 1.

These values of the film thickness dᵤ [nm] , the refractive index nᵤ, and the extinction coefficient kᵤ of the transmittance adjusting film 16 satisfy all relationships according to the equation (1), the equation (2), and the equation (3).

The transmittance and the phase difference of a phase shift film that was formed similarly on another transparent substrate to a light of 193 nm wavelength were measured using a phase shift measurement apparatus (MPM193 manufactured by Lasertec), and the transmittance was 28.0% and the phase difference was 180.0 degrees. The transmittance and the phase difference of a phase shift film and a transmittance adjusting film that were formed similarly on another transparent substrate to a light of 193 nm wavelength were measured, and the transmittance was 6.0% and the phase difference was 178.0 degrees.

### [Manufacture of Phase Shift Mask]

Next, a phase shift mask 200 of Example 2 was manufactured in accordance with the manufacturing method of the phase shift mask described in Embodiment 2, using the mask blank 20 of Example 2.

The manufactured half tone phase shift mask 200 of Example 2 was set on a mask stage of an exposure apparatus using ArF excimer laser as an exposure light, an ArF exposure light was irradiated from the transparent substrate 1 side of the phase shift mask 200, and a pattern was transferred to a resist film on a semiconductor device by exposure. This transfer pattern included a relatively fine pattern and a relatively sparse pattern.

The resist film after the transfer by exposure was subjected to predetermined treatments to form a resist pattern, and the resist pattern was observed using an SEM (Scanning Electron Microscope). As a result, it was discovered that desired transfer patterns were formed for all patterns. From this result, it can be considered that a circuit pattern can be formed with high precision on a semiconductor device with the resist pattern as a mask.

### (Example 3)

### [Manufacture of Mask Blank]

A transparent substrate 1 formed of a synthetic quartz glass with a size of main surfaces of about 152 mm × about 152 mm and a thickness of about 6.35 mm was prepared. End surfaces and main surfaces of the transparent substrate 1 were polished to a predetermined surface roughness, and thereafter subjected to predetermined cleaning treatment and drying treatment. The optical characteristics of the transparent substrate 1 were measured, and the refractive index n was 1.556 and the extinction coefficient k was 0.00 with respect to a wavelength of the ArF exposure light.

Next, the transparent substrate 1 was placed in a film forming sputtering apparatus, and by reactive sputtering using a silicon (Si) target with mixed gas of argon (Ar) gas and nitrogen (N₂) as sputtering gas, a phase shift film 2 consisting of silicon and nitrogen (SiN film Si:N=34.8atom%:65.2atom%) was formed with a thickness of 60 nm in contact with the surface of the transparent substrate 1. Next, by reactive sputtering using a chromium (Cr) target with mixed gas of argon (Ar), carbon dioxide (CO₂), and helium (He) as sputtering gas, a transmittance adjusting film 41 consisting of CrOC was formed with a thickness of 11 nm on the phase shift film 2. Subsequently, by reactive sputtering using a silicon (Si) target with mixed gas of argon (Ar) and oxygen (O₂) as sputtering gas, an etching stopper film 31 consisting of silicon and oxygen (SiO₂ film) was formed with a thickness of 3.0 nm on the transmittance adjusting film 41.

The transmittance and the phase difference of a phase shift film that was formed similarly on another transparent substrate to a light of 193 nm wavelength were measured using a phase shift measurement apparatus (MPM193 manufactured by Lasertec), and the transmittance was 18.6% and the phase difference was 180.0 degrees. The transmittance and the phase difference of a phase shift film and a transmittance adjusting film that were formed similarly on another transparent substrate to a light of 193 nm wavelength were measured, and the transmittance was 6.0% and the phase difference was 191.0 degrees. Since the etching stopper film 31 has a thin film thickness of 3 nm, and has high transmittance similar to that of the transparent substrate, influence of the presence/absence of the etching stopper film 31 to the transmittance and phase difference is negligible.

Moreover, the optical characteristics of the phase shift film 2, the transmittance adjusting film 41, and the etching stopper film 31 were measured, and the phase shift film 2 had the refractive index n of 2.61 and the extinction coefficient k of 0.36, the transmittance adjusting film 41 had the refractive index n_{U} of 1.82 and the extinction coefficient k_{U} of 1.83, and the etching stopper film 31 had the refractive index n of 1.56 and the extinction coefficient k of 0.00.

These values of the film thickness dᵤ [nm], the refractive index nᵤ, and the extinction coefficient kᵤ of the transmittance adjusting film 41 satisfy all relationships according to the equation (1), the equation (2), and the equation (3).

Next, a light shielding film 5 with a trilayer structure was formed with a thickness of 78 nm on the etching stopper film 31. Specifically, the transparent substrate 1 having the phase shift film 2, the transmittance adjusting film 41, and the etching stopper film 31 formed thereon was placed in a film forming sputtering apparatus, and by reactive sputtering using a chromium (Cr) target with mixed gas of argon (Ar), nitrogen (N₂), carbon dioxide (CO₂), and helium (He) as sputtering gas, a first layer consisting of CrOCN was formed with a thickness of 31 nm. Subsequently, by reactive sputtering using a chromium (Cr) target with mixed gas of argon (Ar), nitrogen (N₂), carbon dioxide (CO₂), and helium (He) as sputtering gas, a second layer consisting of CrOCN was formed with a thickness of 41 nm. Further, by reactive sputtering using a chromium (Cr) target with mixed gas of argon (Ar), nitrogen (N₂), and helium (He) as sputtering gas, a third layer consisting of CrN was formed with a thickness of 6 nm.

The optical density (OD) to a light of 193 nm wavelength of the stacked structure of the phase shift film 2, the transmittance adjusting film 41, the etching stopper film 31, and the light shielding film 5 was measured, and the value was 3.2 or more. Subsequently, a resist film 7 of a chemically amplified resist for electron beam writing was formed with a film thickness of 80 nm in contact with the surface of the light shielding film 5 by the spin coating method.

Through the above procedures, a mask blank 30 having a structure where the phase shift film 2, the transmittance adjusting film 41, the etching stopper film 31, the light shielding film 5, and the resist film 7 are stacked on the transparent substrate 1 was manufactured.

### [Manufacture of Phase Shift Mask]

Next, a phase shift mask 300 of Example 3 was manufactured in accordance with the manufacturing method of the phase shift mask described in Embodiment 3, using the mask blank 30 of Example 3.

The manufactured half tone phase shift mask 300 of Example 3 was set on a mask stage of an exposure apparatus using an ArF excimer laser as an exposure light, an ArF exposure light was irradiated from the transparent substrate 1 side of the phase shift mask 300, and a pattern was transferred to a resist film on a semiconductor device by exposure. This transfer pattern included a relatively fine pattern and a relatively sparse pattern.

The resist film after the transfer by exposure was subjected to predetermined treatments to form a resist pattern, and the resist pattern was observed using an SEM (Scanning Electron Microscope). As a result, it was discovered that desired transfer patterns were formed in all patterns. From this result, it can be considered that a circuit pattern can be formed with high precision on a semiconductor device with the resist pattern as a mask.

### [DESCRIPTION OF REFERENCE NUMERALS]

1. transparent substrate, 2. phase shift film
2a. phase shift film having first pattern (phase shift pattern)
2a′. phase shift film partially having first pattern (phase shift pattern)
3. intermediate film
3a. intermediate film having first pattern (intermediate pattern)
3b. intermediate film having second pattern (intermediate pattern)
4. transmittance adjusting film
4a. transmittance adjusting film having first pattern (transmittance adjusting pattern)
4b. transmittance adjusting film having second pattern (transmittance adjusting pattern)
5. light shielding film
5a. light shielding film having first pattern (light shielding pattern)
5b. light shielding film having second pattern (light shielding pattern)
5c. light shielding film having third pattern (light shielding pattern)
6. hard mask film
6a. hard mask film having first pattern (hard mask pattern)
7. resist film
7a. resist film having first pattern (resist pattern)
8b. resist film having second pattern (resist pattern)
9c. resist film having third pattern (resist pattern)
10. mask blank
12. first layer
12a. first layer having first pattern
12a′ . first layer partially having first pattern
13. second layer
13a. second layer having first pattern
14. third layer
14a. third layer having first pattern
15. phase shift film
15a. phase shift film having first pattern (phase shift pattern)
16. transmittance adjusting film
16a. transmittance adjusting film having first pattern (transmittance adjusting pattern)
16b. transmittance adjusting film having second pattern (transmittance adjusting pattern)
20. mask blank
30. mask blank
31. etching stopper film
31a. etching stopper film having first pattern (etching stopper pattern)
31b. etching stopper film having second pattern (etching stopper pattern)
41. transmittance adjusting film
41a. transmittance adjusting film having first pattern (transmittance adjusting pattern)
41b. transmittance adjusting film having second pattern (transmittance adjusting pattern)
100. phase shift mask
200. phase shift mask
300. phase shift mask

1. A mask blank comprising:
a phase shift film on a transparent substrate; and
a transmittance adjusting film on the phase shift film,
wherein the phase shift film generates a phase difference between an exposure light of an ArF excimer laser transmitted through the phase shift film and the exposure light transmitted through the air for a same distance as a thickness of the phase shift film, and
wherein a refractive index nu with respect to a wavelength of the exposure light, an extinction coefficient ku with respect to the wavelength of the exposure light, and a thickness d_{U}[nm] of the transmittance adjusting film satisfy both relationships according to Equation (1) and Equation (2) given below.
$${\text{d}}_{\text{U}} \leq \text{-17} \text{.63} \times {\text{n}}_{\text{U}} {}^{3} \text{+142} \text{.0} \times {\text{n}}_{\text{U}} {}^{2} \text{-364} \text{.9} \times {\text{n}}_{\text{U}} \text{+315} \text{.8}$$
$${\text{d}}_{\text{U}} \geq \text{-2} \text{.805} \times {\text{k}}_{\text{U}} {}^{3} \text{+19} \text{.48} \times {\text{k}}_{\text{U}} {}^{2} \text{-43} \text{.58} \times {\text{k}}_{\text{U}} \text{+38} \text{.11}$$
.

2. The mask blank according to claim 1, wherein the refractive index nᵤ of the transmittance adjusting film is 1.2 or more.

3. The mask blank according to claim 1, wherein the extinction coefficient kᵤ of the transmittance adjusting film is 1.5 or more.

4. The mask blank according to claim 1, wherein the phase shift film transmits the exposure light with a transmittance of 12% or more.

5. The mask blank according to claim 1, wherein the extinction coefficient kᵤ and the thickness dᵤ[nm] of the transmittance adjusting film satisfy the relationship according to Equation (3) given below.
$${\text{d}}_{\text{U}} \leq \text{8} \text{.646} \times {\text{k}}_{\text{U}} {}^{2} \text{-38} \text{.42} \times {\text{k}}_{\text{U}} \text{+61} \text{.89}$$
.

6. The mask blank according to claim 1, wherein the transmittance adjusting film contains silicon and nitrogen.

7. The mask blank according to claim 1 comprising an intermediate film containing silicon and oxygen between the phase shift film and the transmittance adjusting film.

8. The mask blank according to claim 1, wherein the phase shift film comprises an uppermost layer containing silicon and oxygen on a surface that is opposite to a side of the transparent substrate.

9. The mask blank according to claim 1 comprising a light shielding film on the transmittance adjusting film.

10. A phase shift mask comprising:
a phase shift film having a first pattern on a transparent substrate; and
a transmittance adjusting film having a second pattern on the phase shift film,
wherein the phase shift film generates a phase difference between an exposure light of an ArF excimer laser transmitted through the phase shift film and the exposure light transmitted through the air for a same distance as a thickness of the phase shift film, and
wherein a refractive index nu with respect to a wavelength of the exposure light, an extinction coefficient ku with respect to the wavelength of the exposure light, and a thickness dᵤ[nm] of the transmittance adjusting film satisfy both relationships according to Equation (1) and Equation (2) given below.
$${\text{d}}_{\text{U}} \leq \text{-17} \text{.63} \times {\text{n}}_{\text{U}} {}^{3} \text{+142} \text{.0} \times {\text{n}}_{\text{U}} {}^{2} \text{-364} \text{.9} \times {\text{n}}_{\text{U}} \text{+315} \text{.8}$$
$${\text{d}}_{\text{U}} \geq \text{-2} \text{.805} \times {\text{k}}_{\text{U}} {}^{3} \text{+19} \text{.48} \times {\text{k}}_{\text{U}} {}^{2} \text{-43} \text{.58} \times {\text{k}}_{\text{U}} \text{+38} \text{.11}$$
.

11. The phase shift mask according to claim 10, wherein the refractive index nᵤ of the transmittance adjusting film is 1.2 or more.

12. The phase shift mask according to claim 10 or 11, wherein the extinction coefficient kᵤ of the transmittance adjusting film is 1.5 or more.

13. The phase shift mask according to claim 10, wherein the phase shift film transmits the exposure light with a transmittance of 12% or more.

14. The phase shift mask according to claim 10, wherein the extinction coefficient kᵤ and the thickness dᵤ[nm] of the transmittance adjusting film satisfy the relationship according to Equation (3) given below.
$${\text{d}}_{\text{U}} \leq 8.646 \times {\text{k}}_{\text{U}} {}^{2} \text{-38} \text{.42} \times {\text{k}}_{\text{U}} \text{+61} \text{.89}$$
.

15. The phase shift mask according to claim 10, wherein the transmittance adjusting film contains silicon and nitrogen.

16. The phase shift mask according to claim 10 comprising an intermediate film having the second pattern between the phase shift film and the transmittance adjusting film, wherein the intermediate film contains silicon and oxygen.

17. The phase shift mask according to claim 10, wherein the phase shift film comprises an uppermost layer containing silicon and oxygen on a surface that is opposite to a side of the transparent substrate.

18. The phase shift mask according to claim 10 comprising a light shielding film having a third pattern on the transmittance adjusting film.

19. A method of manufacturing a phase shift mask using the mask blank according to claim 9, comprising the steps of:
forming a first pattern in the light shielding film by dry etching;
forming a first pattern in each of the transmittance adjusting film and the phase shift film by dry etching with a light shielding film having the first pattern as a mask;
forming a second pattern in the light shielding film by dry etching;
forming a second pattern in the transmittance adjusting film by dry etching with a light shielding film having the second pattern as a mask; and
forming a third pattern in the light shielding film by dry etching.

20. A method of manufacturing a semiconductor device comprising the step of transferring a transfer pattern to a resist film on a semiconductor substrate by exposure using the phase shift mask according to claim 18.
